(19) United States
(12) Patent Application Publication
(10) Pub. No.: US 2025/0151545 A1
(43) Pub. Date: May 8, 2025

(54) DISPLAY DEVICE AND METHOD FOR FABRICATING THE SAME

(71) Applicant: Samsung Display Co., Ltd., Yongin-Si (KR)

(72) Inventors: Sun Ho KIM, Yongin-si (KR); Yoo Min KO, Yongin-si (KR); Ju Chan PARK, Yongin-si (KR); Pil Suk LEE, Yongin-si (KR); Chung Sock CHOI, Yongin-si (KR)

(21) Appl. No.: 18/740,511

(22) Filed: Jun. 12, 2024

(30) Foreign Application Priority Data
Nov. 7, 2023 (KR) 10-2023-0152560

(51) Int. Cl. H10K 59/131; H10K 59/12; H10K 59/121

(52) U.S. Cl. CPC H10K 59/131; H10K 59/1201; H10K 59/1216

(57) ABSTRACT

Provided are a display device and a method for fabricating the same. The display device includes a circuit layer having a first semiconductor layer; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; and a second semiconductor layer on the first interlayer insulating layer. The second gate conductive layer comprises a first power line. The first gate conductive layer includes a first capacitor electrode that overlaps a part of the first power line. The second semiconductor layer includes a first capacitor auxiliary electrode electrically connected to the first capacitor electrode.

### CROSS-REFERENCE TO RELATED APPLICATION

This application claims priority from Korean Patent Application No. 10-2023-0152560 filed on Nov. 7, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method for fabricating the same.

### 2. Description of the Related Art

With the advance of information-oriented society, more and more demands are placed on display devices for displaying images. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have superior performance in power consumption, response speed, luminous efficiency, luminance, and viewing angle width compared to other display devices.

One surface of the display device may be a display surface including a display area in which an image is displayed and a non-display area that is a periphery of the display area. Emission areas emitting light with respective luminances and colors may be arranged in the display area.

### SUMMARY

As display devices become more high-resolution, each of light emitting pixel drivers becomes smaller, and thus, as a capacitor is disposed in a smaller and more limited space in each of the light emitting pixel drivers. This raises a challenge of capacitance being limited.

Aspects of the present disclosure provide a display device in which capacitance may be increased even with a capacitor being disposed in a limited space, and a method for fabricating the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device includes a substrate comprising a display area having emission areas; a circuit layer disposed on the substrate; and an element layer disposed on the circuit layer. The circuit layer comprises a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first interlayer insulating layer covering the second gate conductive layer; a second semiconductor layer disposed on the first interlayer insulating layer; a third gate insulating layer covering the second semiconductor layer; a third gate conductive layer disposed on the third gate insulating layer; and a second interlayer insulating layer covering the third gate conductive layer. The second gate conductive layer comprises a first power line that transmits a first power. The first gate conductive layer comprises a first capacitor electrode that overlaps a part of the first power line. The second semiconductor layer comprises a first capacitor auxiliary electrode electrically connected to the first capacitor electrode.

The element layer comprises light emitting elements respectively disposed in the emission areas. The circuit layer comprises light emitting pixel drivers that are respectively electrically connected to the light emitting elements and arranged adjacent to each other. Each of the light emitting pixel drivers comprises a first transistor electrically connected between a first node and a second node; a first pixel capacitor electrically connected between the first power line and a third node; a second transistor electrically connected between the first node and a data line that transmits a data signal; a third transistor electrically connected between the second node and the third node; and a fourth transistor electrically connected between the third node and a gate initialization voltage line that transmits a gate initialization voltage. The first node is electrically connected to a first electrode of the first transistor. The second node is electrically connected to a second electrode of the first transistor. The third node is electrically connected to a gate electrode of the first transistor.

Each of the first transistor and the second transistor comprises a channel portion, a first electrode portion, and a second electrode portion disposed in the first semiconductor layer, and a gate electrode disposed in the first gate conductive layer and overlapping the channel portion. Each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode. The first electrode portion is connected to one side of the channel portion. The second electrode portion is connected to the other side of the channel portion. A remaining portion of the second semiconductor layer, excluding the channel portion of the third transistor and the channel portion of the fourth transistor, is conductive.

The gate electrode of the first transistor includes a portion of the first capacitor electrode that overlaps the channel portion of the first transistor. The first pixel capacitor is provided by an overlapping area between the first capacitor electrode and the first power line and an overlapping area between the first capacitor auxiliary electrode and the first power line.

The circuit layer further comprises a first source-drain conductive layer disposed on the second interlayer insulating layer; a first planarization layer covering the first source-drain conductive layer; a second source-drain conductive layer disposed on the first planarization layer; and a second planarization layer covering the second source-drain conductive layer. The first source-drain conductive layer further comprises a gate connection electrode that electrically connects the second electrode portion of the third transistor and the second electrode portion of the fourth transistor to the gate electrode of the first transistor. The gate connection electrode is electrically connected to the first capacitor electrode and the first capacitor auxiliary electrode through a first capacitor connection hole extending to the gate connection electrode. The first capacitor connection hole extending through the second interlayer insulating layer, the third gate insulating layer, the first capacitor auxiliary electrode, the first interlayer insulating layer, and the second gate insulating layer.

The first capacitor auxiliary electrode is electrically connected to the first capacitor electrode through the first capacitor connection hole and the gate connection electrode.

The second transistor is turned on by a scan write signal of a scan write line. Each of the light emitting pixel drivers further comprises a second pixel capacitor electrically connected between the scan write line and the third node; a fifth transistor electrically connected between the first power line and the first node; a sixth transistor electrically connected between the second node and a fourth node; and a seventh transistor electrically connected between the fourth node and an anode initialization voltage line that transmits an anode initialization voltage. The fourth node is electrically connected to one of the light emitting elements.

The first gate conductive layer further comprises the scan write line. The second semiconductor layer further comprises a second capacitor electrode connected to the second electrode portion of the third transistor and the second electrode portion of the fourth transistor and overlapping a part of the scan write line. The second gate conductive layer further comprises a second capacitor auxiliary electrode electrically connected to the second capacitor electrode. The second pixel capacitor is provided by an overlapping area between the second capacitor electrode and the scan write line and an overlapping area between the second capacitor auxiliary electrode and the scan write line.

The gate electrode of the second transistor is provided as another portion of the scan write line that overlaps the channel portion of the second transistor.

The gate connection electrode is electrically connected to the second capacitor electrode and the second capacitor auxiliary electrode through a second capacitor connection hole that extends to the gate connection electrode. The second capacitor connection hole extends through the second interlayer insulating layer, the third gate insulating layer, the second capacitor electrode, and the first interlayer insulating layer, and is in contact with the second capacitor auxiliary electrode.

The second capacitor auxiliary electrode is electrically connected to the second capacitor electrode through the second capacitor connection hole and the gate connection electrode.

According to an aspect of the present disclosure, there is provided a display device comprises a substrate including a display area having emission areas; a circuit layer disposed on the substrate; and an element layer disposed on the circuit layer. The circuit layer comprises a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first interlayer insulating layer covering the second gate conductive layer; a second semiconductor layer disposed on the first interlayer insulating layer; a third gate insulating layer covering the second semiconductor layer; a third gate conductive layer disposed on the third gate insulating layer; a second interlayer insulating layer covering the third gate conductive layer; a first source-drain conductive layer disposed on the second interlayer insulating layer; a first planarization layer covering the first source-drain conductive layer; a second source-drain conductive layer disposed on the first planarization layer; and a second planarization layer covering the second source-drain conductive layer. The element layer comprises light emitting elements respectively disposed in the emission areas. The circuit layer comprises light emitting pixel drivers that are respectively electrically connected to the light emitting elements and arranged adjacent to each other. Each of the light emitting pixel drivers comprises a first transistor electrically connected between a first node and a second node; and a first pixel capacitor electrically connected between a third node and a first power line that transmits a first power. The first node is electrically connected to a first electrode of the first transistor. The second node is electrically connected to a second electrode of the first transistor. The third node is electrically connected to a gate electrode of the first transistor. The first pixel capacitor is provided by an overlapping area between the first capacitor electrode and the first power line and an overlapping area between the first capacitor auxiliary electrode and the first power line. The first capacitor electrode is disposed in the first gate conductive layer and comprises the gate electrode of the first transistor. The first power line is disposed in the second gate conductive layer. The first capacitor auxiliary electrode is disposed in the second semiconductor layer, and electrically connected to the first capacitor electrode through a gate connection electrode and a first capacitor connection hole extending to the gate connection electrode. The gate connection electrode is disposed in the first source-drain conductive layer. The first capacitor connection hole extends through the second interlayer insulating layer, the third gate insulating layer, the first capacitor auxiliary electrode, the first interlayer insulating layer, and the second gate insulating layer.

Each of the light emitting pixel drivers further comprises a second transistor electrically connected between the third node and a data line that transmits a data signal, and turned on by a scan write signal of a scan write line; a third transistor electrically connected between the second node and the third node; a fourth transistor electrically connected between the third node and a gate initialization voltage line that transmits a gate initialization voltage; a second pixel capacitor electrically connected between the scan write line and the third node; a fifth transistor electrically connected between the first power line and the first node; a sixth transistor electrically connected between the second node and the fourth node; and a seventh transistor electrically connected between the fourth node and an anode initialization voltage line that transmits an anode initialization voltage. Each of the first transistor, the second transistor, the fifth transistor, the sixth transistor, and the seventh transistor comprises a channel portion, a first electrode portion, and a second electrode portion disposed in the first semiconductor layer, and a gate electrode disposed in the first gate conductive layer and overlapping the channel portion. Each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode. The first electrode portion is connected to one side of the channel portion. The second electrode portion is connected to the other side of the channel portion. A remaining portion of the second semiconductor layer, excluding the channel portion of the third transistor and the channel portion of the fourth transistor, is conductive.

The second pixel capacitor is provided by an overlapping area between the second capacitor electrode and the scan write line and an overlapping area between the second capacitor auxiliary electrode and the scan write line. The scan write line is disposed in the first gate conductive layer. The second capacitor electrode is disposed in the second semiconductor layer and connected to the second electrode portion of the third transistor and the second electrode portion of the fourth transistor. The second capacitor auxiliary electrode is disposed in the second gate conductive layer, and electrically connected to the second capacitor electrode through the gate connection electrode and a second capacitor connection hole that extends to the gate connection electrode. The second capacitor connection hole extends through the second interlayer insulating layer, the third gate insulating layer, the second capacitor electrode, and the first interlayer insulating layer, and is in contact with the second capacitor auxiliary electrode.

According to an aspect of the present disclosure, a method for fabricating a display device comprises providing a substrate comprising a display area having emission areas; and disposing, on the substrate, a circuit layer comprising light emitting pixel drivers arranged parallel to each other. Each of the light emitting pixel drivers comprises a first transistor electrically connected between a first node and a second node; and a first pixel capacitor electrically connected between a third node and a first power line that transmits a first power. The first node is electrically connected to a first electrode of the first transistor. The second node is electrically connected to a second electrode of the first transistor. The third node is electrically connected to a gate electrode of the first transistor. The disposing of the circuit layer comprises disposing a first semiconductor layer on the substrate; disposing a first gate insulating layer covering the first semiconductor layer; disposing a first gate conductive layer on the first gate insulating layer; disposing a second gate insulating layer covering the first gate conductive layer; disposing a second gate conductive layer on the second gate insulating layer; disposing a first interlayer insulating layer covering the second gate conductive layer; disposing a second semiconductor layer on the first interlayer insulating layer; disposing a third gate insulating layer covering the second semiconductor layer; disposing a third gate conductive layer on the third gate insulating layer; disposing a second interlayer insulating layer covering the third gate conductive layer; disposing first contact holes extending through two or more layers comprising the first interlayer insulating layer among the second interlayer insulating layer, the third gate insulating layer, the second semiconductor layer, the first interlayer insulating layer, the second gate insulating layer, and the first gate insulating layer; disposing at least one second contact hole extending through at least one of the second interlayer insulating layer or the third gate insulating layer; disposing a first source-drain conductive layer on the second interlayer insulating layer; disposing a first planarization layer covering the first source-drain conductive layer; disposing a second source-drain conductive layer on the first planarization layer; and disposing a second planarization layer covering the second source-drain conductive layer. The second gate conductive layer comprises the first power line. The first gate conductive layer comprises a first capacitor electrode that overlaps a part of the first power line. The second semiconductor layer comprises a first capacitor auxiliary electrode electrically connected to the first capacitor electrode. The first source-drain conductive layer comprises a gate connection electrode electrically connected to the first capacitor electrode and the first capacitor auxiliary electrode. The gate electrode of the first transistor is provided as a part of the first capacitor electrode. The first capacitor auxiliary electrode is electrically connected to the first capacitor electrode through the gate connection electrode and a first capacitor connection hole that extends to the gate connection electrode. The first contact holes comprise the first capacitor connection hole extending through the second interlayer insulating layer, the third gate insulating layer, the first capacitor auxiliary electrode, the first interlayer insulating layer, and the second gate insulating layer. The first pixel capacitor is provided by an overlapping area between the first capacitor electrode and the first power line and an overlapping area between the first capacitor auxiliary electrode and the first power line.

Each of the light emitting pixel drivers further comprises a second transistor electrically connected between the third node and a data line that transmits a data signal, and turned on by a scan write signal of a scan write line; a third transistor electrically connected between the second node and the third node; a fourth transistor electrically connected between the third node and a gate initialization voltage line that transmits a gate initialization voltage; a second pixel capacitor electrically connected between the scan write line and the third node; a fifth transistor electrically connected between the first power line and the first node; a sixth transistor electrically connected between the second node and the fourth node; and a seventh transistor electrically connected between the fourth node and an anode initialization voltage line that transmits an anode initialization voltage. Each of the first transistor, the second transistor, the fifth transistor, the sixth transistor, and the seventh transistor comprises a channel portion, a first electrode portion, and a second electrode portion disposed in the first semiconductor layer, and a gate electrode disposed in the first gate conductive layer and overlapping the channel portion. Each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode. The first electrode portion is connected to one side of the channel portion. The second electrode portion is connected to the other side of the channel portion. A remaining portion of the second semiconductor layer, excluding the channel portion of the third transistor and the channel portion of the fourth transistor, is conductive.

The first gate conductive layer further comprises the scan write line. The second semiconductor layer further comprises a second capacitor electrode connected to the second electrode portion of the third transistor and the second electrode portion of the fourth transistor and overlapping a part of the scan write line. The second gate conductive layer further comprises a second capacitor auxiliary electrode electrically connected to the second capacitor electrode. The second capacitor auxiliary electrode is electrically connected to the second capacitor electrode through the gate connection electrode and a second capacitor connection hole that extends to of the gate connection electrode. The first contact holes further comprise the second capacitor connection hole extending through the second interlayer insulating layer, the third gate insulating layer, the second capacitor electrode, and the first interlayer insulating layer. The second pixel capacitor is provided by an overlapping area between the second capacitor electrode and the scan write line and an overlapping area between the second capacitor auxiliary electrode and the scan write line.

In the disposing of the first contact holes, the second capacitor connection hole is in contact with the second capacitor auxiliary electrode.

The disposing of the first contact holes may include using an etching material that contains carbon tetrafluoride (CF₄) and oxygen (O₂). the disposing of the second contact hole includes using an etching material that contains carbon tetrafluoride (CF₄) and argon (Ar).

The display device according to embodiments may include a substrate, a circuit layer, and an element layer. The circuit layer may include a first semiconductor layer disposed on the substrate, a first gate insulating layer covering the first semiconductor layer, a first gate conductive layer disposed on the first gate insulating layer, a second gate insulating layer covering the first gate conductive layer, a second gate conductive layer disposed on the second gate insulating layer, a first interlayer insulating layer covering the second gate conductive layer, a second semiconductor layer disposed on the first interlayer insulating layer, a third gate insulating layer covering the second semiconductor layer, a third gate conductive layer disposed on the third gate insulating layer, and a second interlayer insulating layer covering the third gate conductive layer.

The second gate conductive layer may include a first power line that transmits a first power.

The first gate conductive layer may include a first capacitor electrode that overlaps a part of the first power line.

The second semiconductor layer may include a first capacitor auxiliary electrode electrically connected to the first capacitor electrode.

According to embodiments, the substrate may include a display area in which emission areas are arranged. The element layer may include light emitting elements respectively disposed in the emission areas. The circuit layer may include light emitting pixel drivers that are respectively electrically connected to the light emitting elements of the element layer and arranged parallel to each other.

Each of the light emitting pixel drivers may include a first transistor electrically connected between a first node and a second node, a second transistor electrically connected between the first power line and a third node, a third transistor electrically connected between the second node and the third node, and a fourth transistor electrically connected between the third node and a gate initialization voltage line that transmits a gate initialization voltage. Here, the first node is electrically connected to the first electrode of the first transistor, the second node is electrically connected to the second electrode of the first transistor, and the third node is electrically connected to a gate electrode of the first transistor.

A first pixel capacitor may be provided in an overlapping area between the first capacitor electrode and the first power line and an overlapping area between the first capacitor auxiliary electrode and the first power line.

That is, according to embodiments, as the circuit layer includes the first capacitor auxiliary electrode disposed in the second semiconductor layer, the first pixel capacitor may be provided not only in an overlapping area between the first capacitor electrode and the first power line, but also in an overlapping area between the first capacitor auxiliary electrode and the first power line. Accordingly, the capacitance of the first pixel capacitor electrically connected to the first power line may increase.

According to embodiments, the circuit layer may further include a first source-drain conductive layer disposed on the second interlayer insulating layer, a first planarization layer covering the first source-drain conductive layer, a second source-drain conductive layer disposed on the first planarization layer, and a second planarization layer covering the second source-drain conductive layer.

The first source-drain conductive layer may further include a gate connection electrode that electrically connects a second electrode portion of the third transistor and a second electrode portion of the fourth transistor to the gate electrode of the first transistor.

According to one embodiment, the gate connection electrode may be electrically connected to the first capacitor electrode and the first capacitor auxiliary electrode through a first capacitor connection hole that extends to the gate connection electrode.

The first capacitor connection hole may extend through the second interlayer insulating layer, the third gate insulating layer, the first capacitor auxiliary electrode, the first interlayer insulating layer, and the second gate insulating layer to be in contact with the first capacitor electrode.

That is, the first capacitor auxiliary electrode may be electrically connected to the first capacitor electrode through the first capacitor connection hole and the gate connection electrode.

In this way, according to one embodiment, the first capacitor auxiliary electrode has the first capacitor connection hole extending therethrough, so that electrical connection may be implemented between the first capacitor electrode and the first capacitor auxiliary electrode by the gate connection electrode disposed in the first capacitor connection hole. That is, the width of the first pixel capacitor may be reduced to the extent that a connection hole in contact with the first capacitor auxiliary electrode is not disposed for the electrical connection between the first capacitor electrode and the first capacitor auxiliary electrode. Accordingly, it may be advantageous in achieving the high resolution of the display device.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view illustrating a display device according to embodiments;

FIG. 2 is a plan view illustrating the display device of FIG. 1;

FIG. 3 is a cross-sectional view taken along line A-A′ of FIG. 2;

FIG. 4 is a layout diagram illustrating part B of FIG. 2;

FIG. 5 is an equivalent circuit diagram showing the light emitting pixel driver of FIG. 4 according to embodiments;

FIG. 6 is a cross-sectional view illustrating a first transistor, a sixth transistor, and a light emitting element shown in FIG. 5;

FIG. 7 is a plan view illustrating a partial area including the first transistor, second transistor, and third transistor in the light emitting pixel driver according to one embodiment;

FIG. 8 is a plan view illustrating a first semiconductor layer, a first gate conductive layer, a second gate conductive layer, a second semiconductor layer, and a third gate conductive layer in FIG. 7;

FIG. 9 is a cross-sectional view taken along line C-C′ of FIG. 7;

FIG. 10 is a cross-sectional view taken along line D-D′ of FIG. 7;

FIG. 11 is a flowchart illustrating a method for fabricating the display device according to one embodiment; and

FIGS. 12, 13, 14, 15, 16, 17, 18, 19, 20, 21, 22, 23, and 24 are process diagrams illustrating the process stages of FIG. 11.

### DETAILED DESCRIPTION OF THE EMBODIMENTS

Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art, and the present disclosure will only be defined by the appended claims.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the present disclosure is not limited to the illustrated details.

It will be understood that, although the terms first, second, third, etc., may be used herein to describe various elements, these elements should not be limited to any order by these terms. These terms are only used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in various ways. The embodiments may be implemented independently from each other, or may be implemented together in a co-dependent relationship.

Hereinafter, specific embodiments will be described with reference to the accompanying drawings.

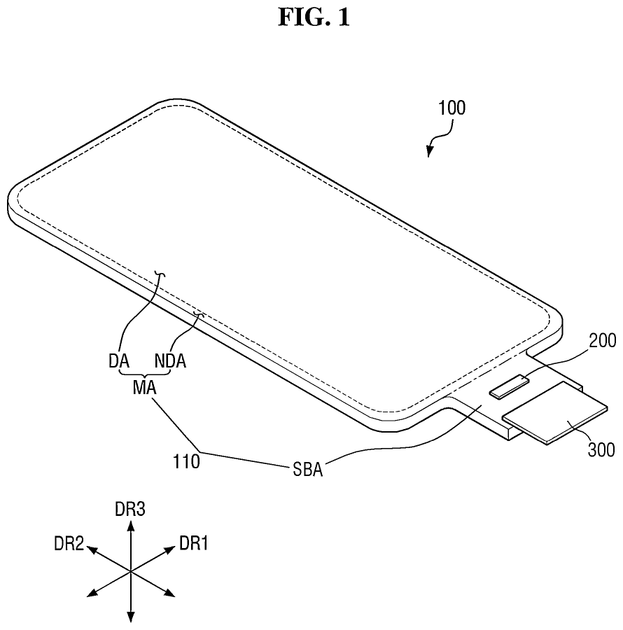

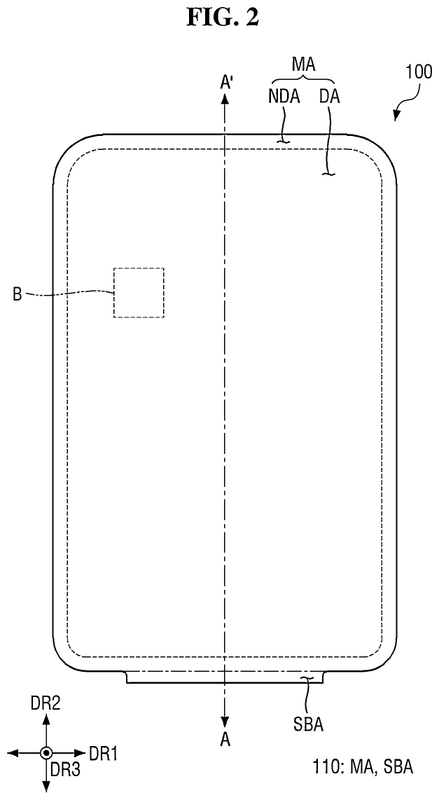

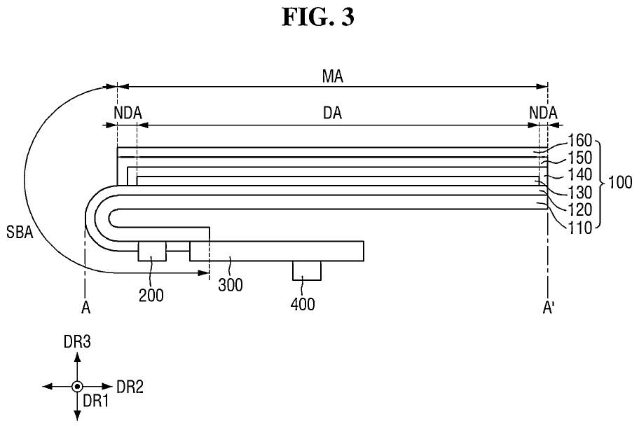

FIG. 1 is a perspective view illustrating a display device according to an embodiment. FIG. 2 is a plan view illustrating the display device of FIG. 1. FIG. 3 is a cross-sectional view taken along line A-A′ of FIG. 2.

Referring to FIGS. 1 and 2, a display device 100 may display a moving image or a still image. The display device 100 may be used as a display screen for various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at the edges and having a constant curvature or a varying curvature. In addition, the display device 100 may be formed to be flexible so that it can be curved, bent, folded, or rolled.

As illustrated in FIGS. 1, 2 and 3, the display device 100 includes a substrate 110.

The substrate 110 may include a main region MA corresponding to a display surface of the display device 100 and a sub-region SBA protruding from one side of the main region MA.

As shown in FIG. 2, the main region MA may include a display area DA disposed at the center region and surrounding areas excluding edge region, and a non-display area NDA disposed around the display area DA, such as near the edge region.

The display area DA may, in plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a predetermined curvature or may be right-angled. The planar shape of the display area DA is not limited to the rectangular shape, and may be formed in another polygonal shape, a circular shape or an elliptical shape.

The non-display area NDA may be disposed at the edge region of the main region MA to surround the display area DA.

The sub-region SBA may be a region connected to and extending from one side of the non-display area NDA of the main region MA in the second direction DR2.

Part of the sub-region SBA may be bent, as depicted in FIG. 3, while another part of the sub-region SBA may be disposed on the rear surface of the display device 100.

FIGS. 2 and 3 illustrate the display device 100 with a part of the sub-region SBA in a bent state.

Referring to FIG. 3, the display device 100 according to an embodiment includes the substrate 110, a circuit layer 120 disposed on the substrate 110, and an element layer 130 disposed on the circuit layer 120.

The display device 100 according to embodiments may further include an encapsulation layer 140 disposed on the element layer 130, and a touch sensor layer 150 disposed on the encapsulation layer 140.

Also, the display device 100 according to embodiments may further include a polarization layer 160 disposed on the touch sensor layer 150 to reduce reflection of external light.

The substrate 110 may be formed of an insulating material such as a polymer resin. For example, the substrate 110 may be formed of polyimide. The substrate 110 may be a flexible substrate which can be bent, folded or rolled.

Alternatively, the substrate 110 may be formed of an insulating material such as glass or the like.

The substrate 110 may include the main region MA and the sub-region SBA. The main region MA may include the display area DA and the non-display area NDA.

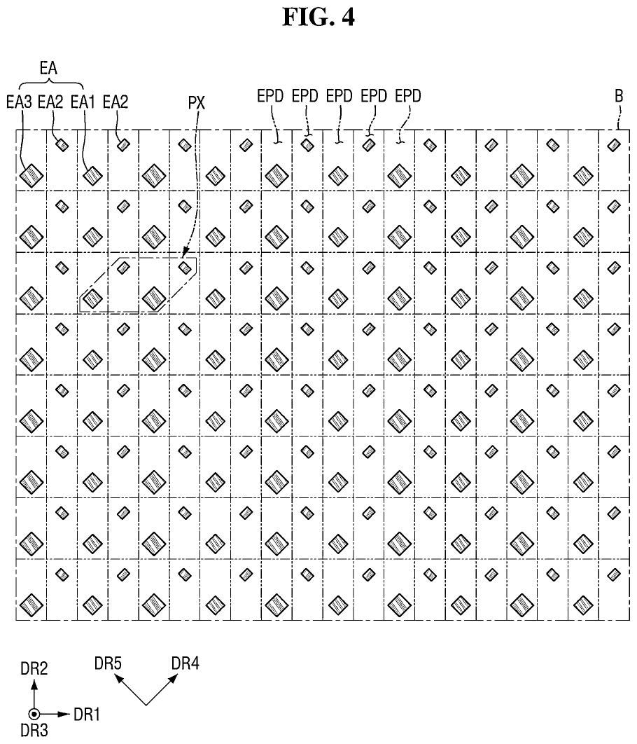

FIG. 4 is a layout diagram illustrating part B of FIG. 2.

Referring to FIG. 4, the display area DA of the display device 100 according to embodiments may include the emission areas EA. In addition, the display area DA may further include a non-emission area disposed in a gap between the emission areas EA.

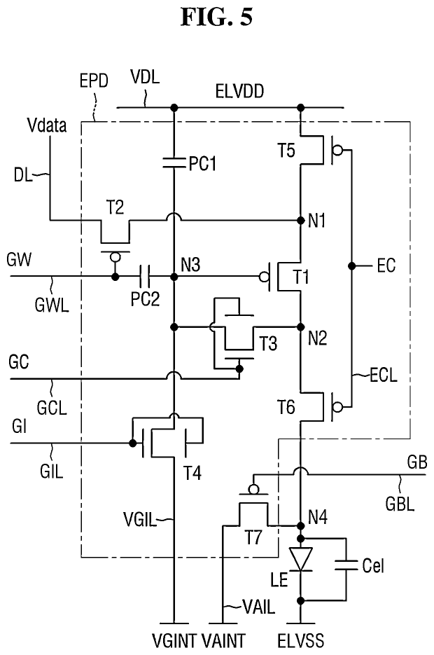

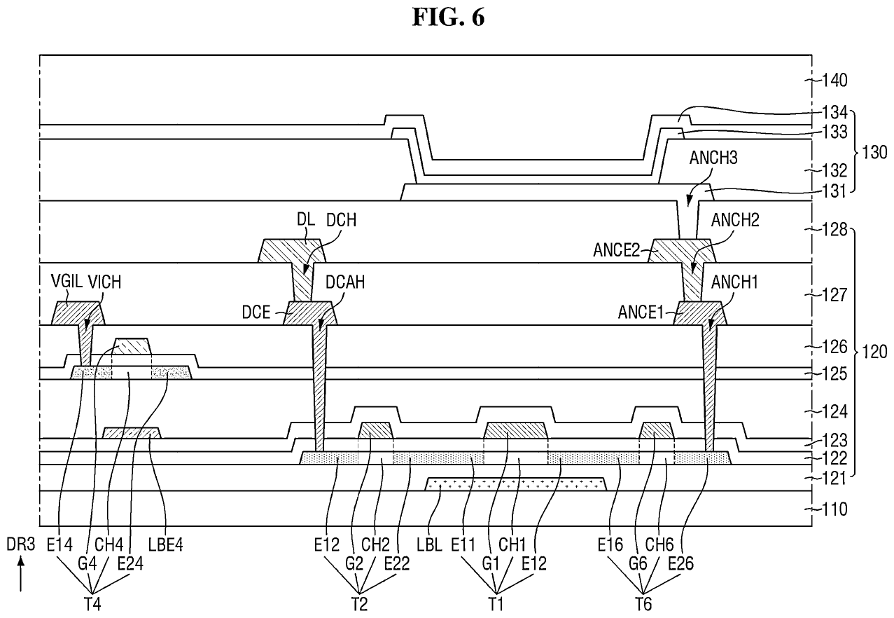

Light emitting pixel drivers EPD respectively corresponding to the emission areas EA may be arranged in the display area DA adjacent to each other in the first direction DR1 and the second direction DR2. The light emitting pixel drivers EPD may be respectively electrically connected to light emitting elements LE (see FIGS. 5 and 6) of the element layer 130 respectively disposed in the emission areas EA.

The emission areas EA may have a rhombus shape or a rectangular shape in plan view. However, this is only an example, and the planar shape of the emission areas EA according to one embodiment is not limited to that illustrated in FIG. 4. That is, in plan view, the emission areas EA may have a polygonal shape such as a square, a pentagon, a hexagon, etc., or may have a circular or elliptical shape including the edge of a curve.

The emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately arranged in at least one of the first direction DR1 and the second direction DR2.

The second emission areas EA2 may be arranged side by side in at least one of the first direction DR1 and the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

A pixel PX may be a basic unit for displaying various colors including white with a predetermined luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 5 is an equivalent circuit diagram showing the light emitting pixel driver of FIG. 4 according to embodiments.

Referring to FIG. 5, one of the light emitting elements LE of the element layer 130 may be electrically connected between one of the light emitting pixel drivers EPD of the circuit layer 120 and a second power ELVSS.

That is, the anode electrode of the light emitting element LE is electrically connected to the light emitting pixel driver EPD, and the cathode electrode of the light emitting element LE may be applied with the second power ELVSS lower than a first power ELVDD.

A capacitor Cel connected in parallel with the light emitting element LE stores a parasitic capacitance between the anode electrode and the cathode electrode.

The circuit layer 120 may further include a first power line VDL that transmits the first power ELVDD, a gate initialization voltage line VGIL that transmits a gate initialization power VGINT, and an anode initialization voltage line VAIL that transmits an anode initialization power VAINT.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light emitting pixel driver EPD of the circuit layer 120 may include a first transistor T1 configured to generate a driving current for driving the light emitting element LE, two or more transistors T2 to T7 electrically connected to the first transistor T1, and at least one pixel capacitor PC1.

The first transistor T1 is connected in series with the light emitting element LE between the first power ELVDD and the second power ELVSS.

The first transistor T1 may be electrically connected between the first node N1 and the second node N2. The first node N1 is electrically connected to the first electrode (e.g., source electrode) of the first transistor T1. The second node N2 is electrically connected to the second electrode (e.g., drain electrode) of the first transistor T1.

In other words, the first electrode (e.g., the source electrode) of the first transistor T1 may be electrically connected to a first power line VDL through the fifth transistor T5. Further, the second electrode (e.g., the drain electrode) of the first transistor T1 may be electrically connected to the anode electrode of the light emitting element LE through the sixth transistor T6.

The first pixel capacitor PC1 may be electrically connected between the first power line VDL and a third node N3. The third node N3 is electrically connected to the gate electrode of the first transistor T1.

That is, the gate electrode of the first transistor T1 may be electrically connected to the first power line VDL through the first pixel capacitor PC1.

A second pixel capacitor PC2 may be electrically connected between the scan write line GWL and the third node N3.

That is, the gate electrode of the first transistor T1 may be electrically connected to the scan write line GWL through the second pixel capacitor PC2.

Due to the voltages respectively charged in the first pixel capacitor PC1 and the second pixel capacitor PC2, the gate electrode of the first transistor T1 may be maintained at a predetermined potential corresponding to the first power ELVDD and the scan write signal GW during each image frame period.

In addition, since the second pixel capacitor PC2 is charged with the scan write signal GW, the turn-on state of the second transistor T2 may be stably maintained by the voltage charged in the second pixel capacitor PC2.

The second transistor T2 may be electrically connected between the data line DL and the first node N1.

In other words, the second transistor T2 may be electrically connected between the first electrode of the first transistor T1 and the data line DL. The second transistor T2 may be turned on by the scan write signal GW of the scan write line GWL.

That is, the first electrode of the first transistor T1 may be electrically connected to the data line DL through the second transistor T2.

The fifth transistor T5 may be electrically connected between the first node N1 and the first power line VDL.

The sixth transistor T6 may be electrically connected between the second node N2 and the fourth node N4. The fourth node N4 is electrically connected to the anode electrode of the light emitting element LE.

The fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When a data signal Vdata of the data line DL is transmitted to the first electrode of the first transistor T1 through the turned-on second transistor T2, the voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, i.e., the gate-to-source voltage difference, becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light emitting element LE between the first power line VDL and a second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1. The third transistor T3 may be turned on by the gate control signal GC of the gate control line GCL.

Through the turned-on third transistor T3, the voltage difference between the second node N2 and the third node N3 may be reset.

The fourth transistor T4 may be electrically connected between the gate initialization voltage line VGIL and the third node N3. That is, the fourth transistor T4 may be connected between the gate electrode of the first transistor T1 and the gate initialization voltage line VGIL. The fourth transistor T4 may be turned on by the scan initialization signal GI of the scan initialization line GIL.

Through the turned-on fourth transistor T4, the potential of the third node N3 may be initialized to a gate initialization voltage VGINT.

The third transistor T3 and the fourth transistor T4 may be provided as N-type MOSFETs.

The seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL. The seventh transistor T7 may be turned on by the bias control signal GB of the bias control line GBL.

Through the turned-on seventh transistor T7, the potential of the fourth node N4, that is, the anode electrode of the light emitting element LE, may be initialized to an anode initialization voltage VAINT.

Among the first to eighth transistors T1 to T8, each of the transistors T1, T2, and T5 to T8 except for the third transistor T3 and the fourth transistor T4 may be implemented as a P-type MOSFET.

That is, while each of the third transistor T3 and the fourth transistor T4 among the first to eighth transistors T1 to T8 included in the light emitting pixel driver EPD is implemented as an N-type MOSFET, each of the remaining transistors T1, T2, and T5 to T8 except for these two may be implemented as a P-type MOSFET.

Accordingly, according to embodiments, the circuit layer 120 may include a first semiconductor layer and a second semiconductor layer.

FIG. 6 is a cross-sectional view illustrating a first transistor, a sixth transistor, and a light emitting element shown in FIG. 5.

Referring to FIG. 6, the display device 100 according to embodiments may include the substrate 110, the circuit layer 120 on the substrate 110, the element layer 130 on the circuit layer 120, and the encapsulation layer 140 on the element layer 130.

According to embodiments, the circuit layer 120 may include a first semiconductor layer CH1, E11, E21, CH2, E12, E22, CH6, E16, and E26 disposed on the substrate 110, a first gate insulating layer 122 covering the first semiconductor layer, a first gate conductive layer G1, G2, and G6 disposed on the first gate insulating layer 122, a second gate insulating layer 123 covering the first gate conductive layer, a second gate conductive layer LBE4 disposed on the second gate insulating layer 123, a first interlayer insulating layer 124 covering the second gate conductive layer, a second semiconductor layer CH4, E14, and E24 disposed on the first interlayer insulating layer 124, a third gate insulating layer 125 covering the second semiconductor layer, a third gate conductive layer G4 disposed on the third gate insulating layer 125, a second interlayer insulating layer 126 covering the third gate conductive layer, a first source-drain conductive layer ANCE1, VGIL, and DCE disposed on the second interlayer insulating layer 126, a first planarization layer 127 covering the first source-drain conductive layer, a second source-drain conductive layer DL and ANCE2 disposed on the first planarization layer 127, and a second planarization layer 128 covering the second source-drain conductive layer.

According to embodiments, the circuit layer 120 may further include a buffer layer 121 covering the substrate 110. In this case, the first semiconductor layer may be disposed on the buffer layer 121. The buffer layer 121 may cover a light blocking layer LBL on the substrate 110.

The light blocking layer LBL may overlap the channel portion CH1 of the first transistor T1.

As previously described with reference to FIG. 5, the circuit layer 120 may include the light emitting pixel drivers EPD electrically connected to the light emitting elements LE disposed in the emission areas EA, respectively, and wires that transmit various signals and voltages to the light emitting pixel drivers EPD. The light emitting pixel drivers EPD may include the first transistor T1 and two or more of the transistors T2 to T7 electrically connected to the first transistor T1.

As illustrated in FIG. 6, according to embodiments, the first transistor T1 may include the channel portion CH1, the first electrode portion E11, and the second electrode portion E21 disposed in the first semiconductor layer on the substrate 110, and the gate electrode G1 disposed in the first gate conductive layer on the first gate insulating layer 122.

The first electrode portion E11 may be connected to one side of the channel portion CH1, and the second electrode portion E21 may be connected to the other side of the channel portion CH1.

The first electrode portion E11 and the second electrode portion E21 may be doped at a higher concentration than the channel portion CH1.

The gate electrode G1 may overlap the channel portion CH1.

Similarly, the second transistor T2 may include the channel portion CH2, the first electrode portion E12, and the second electrode portion E22 disposed in the first semiconductor layer on the substrate 110, and the gate electrode G2 disposed in the first gate conductive layer on the first gate insulating layer 122 and overlapping the channel portion CH2.

In addition, the six transistor T6 may include the channel portion CH6, the first electrode portion E16, and the second electrode portion E26 disposed in the first semiconductor layer on the substrate 110, and the gate electrode G6 disposed in the first gate conductive layer on the first gate insulating layer 122 and overlapping the channel portion CH6.

The first electrode portion E12 of the second transistor T2 may be electrically connected to the data line DL through a data connection electrode DCE.

The data connection electrode DCE may be disposed in the first source-drain conductive layer on the second interlayer insulating layer 126, and may be electrically connected to the first electrode portion E12 of the second transistor T2 through a data auxiliary connection hole DCAH. The data auxiliary connection hole DCAH may extend through the second interlayer insulating layer 126, the third gate insulating layer 125, the first interlayer insulating layer 124, the second gate insulating layer 123, and the first gate insulating layer 122.

The data line DL may be disposed in the second source-drain conductive layer on the first planarization layer 127, and may be electrically connected to the data connection electrode DCE through a data connection hole DCH extending through the first planarization layer 127.

The second electrode portion E22 of the second transistor T2 may be connected to the first electrode portion E11 of the first transistor T1.

The second electrode portion E21 of the first transistor T1 may be connected to the first electrode portion E16 of the sixth transistor T6.

The second electrode portion E26 of the sixth transistor T6 may be electrically connected to the anode electrode 131 through the first anode connection electrode ANCE1 and the second anode connection electrode ANCE2.

The first anode connection electrode ANCE1 may be disposed in the first source-drain conductive layer on the second interlayer insulating layer 126, and may be electrically connected to the second electrode portion E26 of the six transistor T6 through a first anode contact hole ANCH1. The first anode contact hole ANCH1 may extend through the second interlayer insulating layer 126, the third gate insulating layer 125, the first interlayer insulating layer 124, the second gate insulating layer 123, and the first gate insulating layer 122.

The second anode connection electrode ANCE2 may be disposed on the second source-drain conductive layer on the first planarization layer 127, and electrically connected to the first anode connection electrode ANCE1 through a second anode contact hole ANCH2 extending through the first planarization layer 127.

The anode electrode 131 may be disposed on the second planarization layer 128, and may be electrically connected to the second anode connection electrode ANCE2 through a third anode contact hole ANCH3 extending through the second planarization layer 128.

According to embodiments, since the fifth transistor T5 and the seventh transistor T7 have substantially the same structure as the first transistor T1, the second transistor T2, and the sixth transistor T6, redundant description is omitted below.

The first gate conductive layer on the first gate insulating layer 122 not only may include the gate electrode of each of the first transistor T1, the second transistor T2, the fifth transistor T5, the sixth transistor T6, the seventh transistor T7, and the eighth transistor T8, but also may further include the scan write line GWL electrically connected to the gate electrode G2 of the second transistor T2, and the bias control line GBL electrically connected to the gate electrode of the seventh transistor T7.

In addition, the first gate conductive layer may further include the emission control line ECL electrically connected to the gate electrode of the fifth transistor T5 and the gate electrode of the sixth transistor T6.

According to embodiments, the fourth transistor T4, in order to be provided in a different type from the first transistor T1, the second transistor T2, and the sixth transistor T6, may include the channel portion CH4, the first electrode portion E14, and the second electrode portion E24 disposed in the second semiconductor layer on the first interlayer insulating layer 124.

That is, the fourth transistor T4 may include the channel portion CH4, the first electrode portion E14, and the second electrode portion E24 disposed in the second semiconductor layer on the first interlayer insulating layer 124, the gate electrode G4 disposed in the third gate conductive layer on the third gate insulating layer 125 and overlapping the channel portion CH4, and a light blocking electrode LBE4 disposed in the second gate conductive layer on the second gate insulating layer 123 and overlapping the channel portion CH4.

The third transistor T3 has substantially the same structure as the fourth transistor T4, and duplicate description will be omitted below.

The first source-drain conductive layer on the second interlayer insulating layer 126 may further include the gate initialization voltage line VGIL and a data connection electrode DCE.

The gate initialization voltage line VGIL may be electrically connected to the first electrode portion E14 of the fourth transistor T4 through an initialization connection hole VICH.

The data line DL may be disposed in the second source-drain conductive layer on the first planarization layer 127.

The element layer 130 may include the light emitting elements LE disposed on the second planarization layer 128 and respectively corresponding to the emission areas EA.

Each of the light emitting elements LE may include an anode electrode 131 and the cathode electrode 134 facing each other, and a light emitting layer 133 disposed therebetween.

That is, the element layer 130 may include the anode electrodes 131 respectively corresponding to the emission areas EA, a pixel defining layer 132 corresponding to a non-emission area NEA and covering the edge of the anode electrode 131, light emitting layers 133 respectively disposed on the anode electrodes 131, and the cathode electrode 134 disposed on the light emitting layers 133 and the pixel defining layer 132.

Alternatively, each of the light emitting elements LE may further include a first common layer (not shown) disposed between the anode electrode 131 and the light emitting layer 133, and a second common layer (not shown) disposed between the light emitting layer 133 and the cathode electrode 134.

The anode electrode 131 may be disposed in each of the emission areas EA and may be electrically connected to one light emitting pixel driver EPD of the circuit layer 120. This anode electrode 131 may be referred to as a pixel electrode.

The anode electrode 131 may be electrically connected to the second anode connection electrode ANCE2 through the third anode contact hole ANCH3 extending through the second planarization layer 128.

The light emitting layer 133 may be formed of an organic light emitting material that converts electron-hole pairs into light.

The cathode electrode 134 may be disposed in the display area DA including the emission areas EA. The second power ELVSS may be commonly applied to the cathode electrode 134. The cathode electrode 134 may be referred to as a common electrode.

The encapsulation layer 140 may be disposed on the circuit layer 120 and cover the element layer 130.

In an embodiment, the encapsulation layer 140 may include a first encapsulation layer disposed on the element layer 130 and made of an inorganic insulating material, a second encapsulation layer disposed on the first encapsulation layer, overlapping the element layer 130, and made of an organic insulating material, and a third encapsulation layer disposed on the first encapsulation layer, covering the second encapsulation layer, and made of an inorganic insulating material.

Meanwhile, as the display device 100 becomes higher resolution, the number of light emitting pixel drivers EPD disposed in the main region MA is increased. That is, since a greater number of light emitting pixel drivers EPD are disposed in the main region MA of a limited width, the width of each of the light emitting pixel drivers EPD may be reduced.

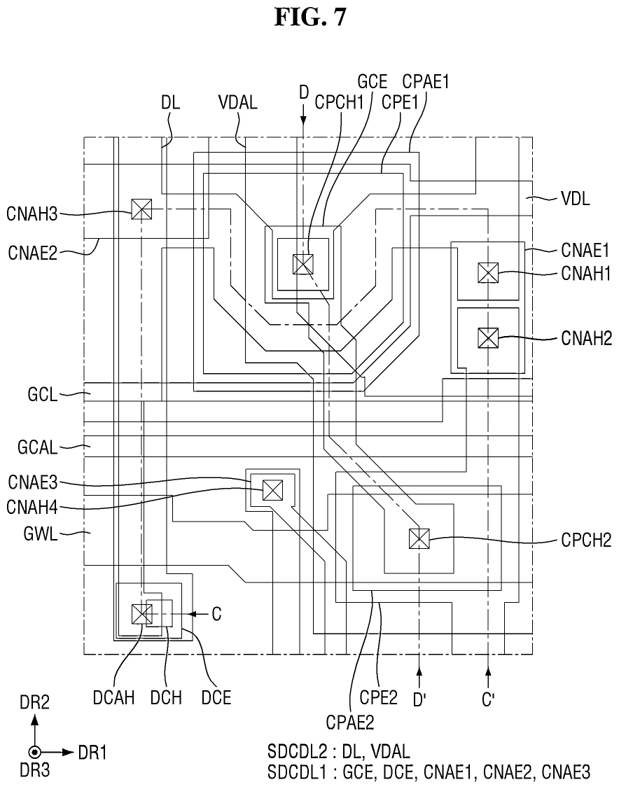

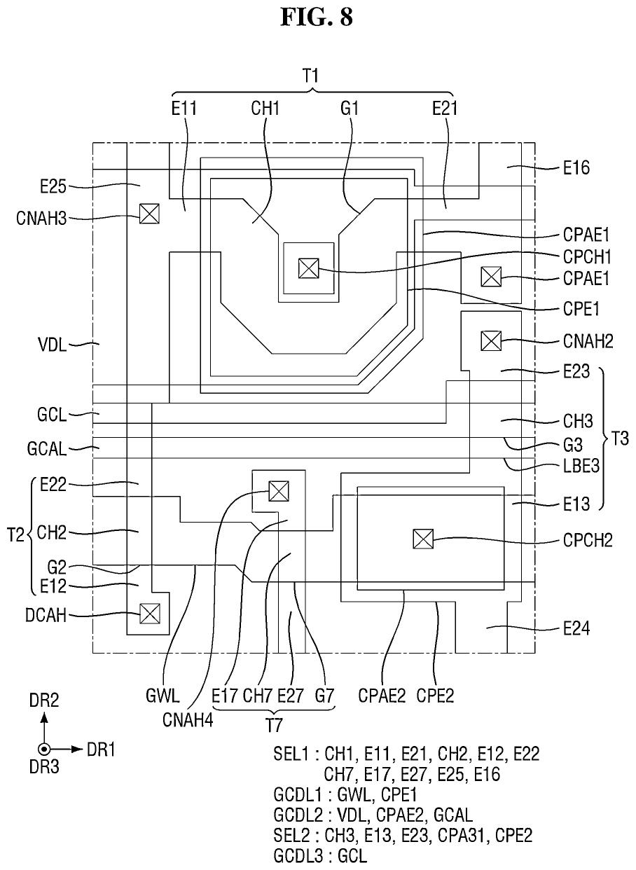

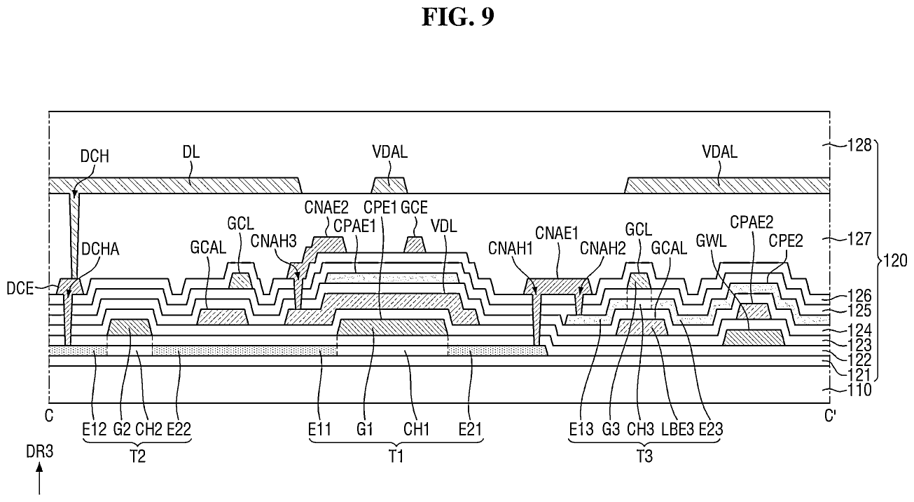

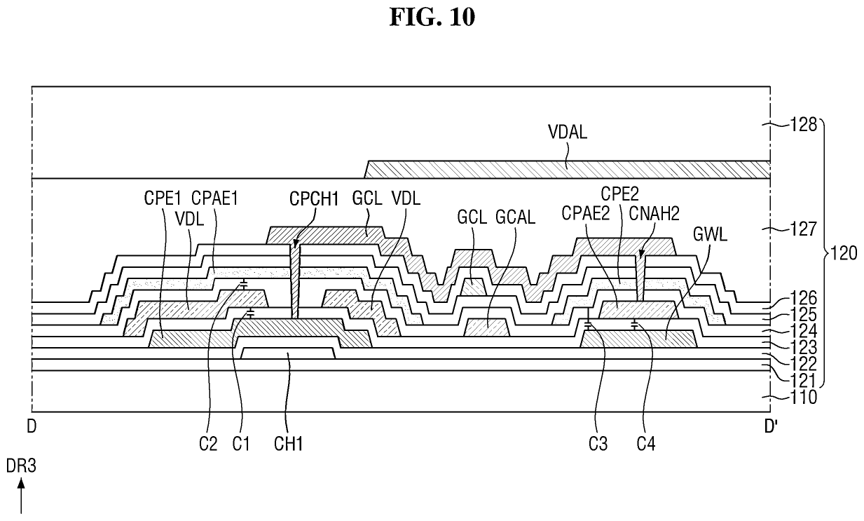

FIG. 7 is a plan view illustrating a partial area including the first transistor, second transistor, and third transistor in the light emitting pixel driver according to one embodiment. FIG. 8 is a plan view illustrating a first semiconductor layer, a first gate conductive layer, a second gate conductive layer, a second semiconductor layer, and a third gate conductive layer in FIG. 7. FIG. 9 is a cross-sectional view taken along line C-C′ of FIG. 7. FIG. 10 is a cross-sectional view taken along line D-D′ of FIG. 7.

Referring to FIGS. 7, 8, 9, and 10, the circuit layer 120 according to one embodiment may include a first semiconductor layer SEL1 (CH1, E11, E21, CH2, E12, E22, CH7, E17, E27, E25, and E16) disposed on the substrate 110, the first gate insulating layer 122 covering the first semiconductor layer SEL1, a first gate conductive layer GCDL1 (GWL and CPE1) disposed on the first gate insulating layer 122, the second gate insulating layer 123 covering the first gate conductive layer GCDL1, a second gate conductive layer GCDL2 (VDL, CPAE2, and GCAL) disposed on the second gate insulating layer 123, the first interlayer insulating layer 124 covering the second gate conductive layer GCDL2, a second semiconductor layer SEL2 (CH3, E13, E23, CPAE1, and CPE2) disposed on the first interlayer insulating layer 124, the third gate insulating layer 125 covering the second semiconductor layer SEL2, a third gate conductive layer GCDL3 (GCL) disposed on the third gate insulating layer 125, and the second interlayer insulating layer 126 covering the third gate conductive layer GCDL3.

The circuit layer 120 according to one embodiment may further include a first source-drain conductive layer SDCDL1 (GCE, DCE, CNAE1, CNAE2, and CNAE3) disposed on the second interlayer insulating layer 126, the first planarization layer 127 covering the first source-drain conductive layer SDCDL1, a second source-drain conductive layer SDCDL2 (DL and VDAL) disposed on the first planarization layer 127, and the second planarization layer 128 covering the second source-drain conductive layer SDCDL2.

According to one embodiment, the circuit layer 120 may further include the buffer layer 121 covering the substrate 110.

As illustrated in FIG. 8, the first semiconductor layer SEL1 on the substrate 110 may include the channel portion CH1, the first electrode portion E11, and the second electrode portion E21 of the first transistor T1, the channel portion CH2, the first electrode portion E12, and the second electrode portion E22 of the second transistor T2, and the channel portion CH7, the first electrode portion E17, and the second electrode portion E27 of the seventh transistor T7.

The first semiconductor layer SEL1 may further include the second electrode portion E25 of the fifth transistor T5 connected to the first electrode portion E11 of the first transistor T1, and the first electrode portion E16 of the sixth transistor T6 connected to the second electrode portion E21 of the first transistor T1.

That is, since the fifth transistor T5 and the sixth transistor T6 are provided in the same polarity form as the first transistor T1, the first semiconductor layer SEL1 may further include a channel portion, a first electrode portion, and a second electrode portion of each of the fifth transistor T5 and the sixth transistor T6.

The first electrode portion E11 of the first transistor T1 may correspond to the first node N1 (see FIG. 5). That is, the first electrode portion E11 of the first transistor T1 may be connected to the second electrode portion E22 of the second transistor T2 and the second electrode portion E25 of the fifth transistor T5.

The second electrode portion E21 of the first transistor T2 may correspond to the second node N2 (see FIG. 5). That is, the second electrode portion E21 of the first transistor T2 may be connected to the first electrode portion E13 of the third transistor T3.

As illustrated in FIGS. 7 and 9, the second electrode portion E21 of the first transistor T2 may be electrically connected to the first electrode portion E16 of the sixth transistor T6 through the first connection auxiliary electrode CNAE1.

As illustrated in FIG. 8, the first gate conductive layer GCDL1 on the first gate insulating layer 122 may include the first capacitor electrode CPE1 and the scan write line GWL.

The first capacitor electrode CPE1 is used to provide the first pixel capacitor PC1 (see FIG. 5) between the first power ELVDD and the third node N3.

As illustrated in FIG. 9, the gate electrode G1 of the first transistor T1 may be provided as a portion of the first capacitor electrode CPE1 that overlaps the channel portion CH1 of the first transistor T1.

The gate electrode G2 of the second transistor T2 may be provided as a portion of the scan write line GWL that overlaps the channel portion CH2 of the second transistor T2.

Meanwhile, the seventh transistor T7 may be turned on by the bias control signal GB (see FIG. 5) of the bias control line GBL (see FIG. 5).

As an example, the bias control signal GB may be a front-end scan write signal.

In this case, as illustrated in FIG. 8, the gate electrode G7 of the seventh transistor T7 (hereinafter referred to as the “rear-stage seventh transistor”) of the light emitting pixel driver (not illustrated) adjacent to the second direction DR2 may be provided as another portion of the scan write line GWL that overlaps the channel portion CH7 of the rear-stage seventh transistor T7.

As illustrated in FIG. 8, the second gate conductive layer GCDL2 on the second gate insulating layer 123 may include the first power line VDL.

The first power line VDL may extend in the first direction DR1.

As illustrated in FIGS. 8 and 10, the first capacitor electrode CPE1 may overlap a part of the first power line VDL.

The second gate conductive layer GCDL2 may further include the second capacitor auxiliary electrode CPAE2.

As illustrated in FIGS. 8 and 9, the second gate conductive layer GCDL2 may further include the gate control auxiliary line GCAL. The gate control auxiliary line GCAL may extend in the first direction DR1.

A portion of the gate control auxiliary line GCAL that overlaps the channel portion CH3 of the third transistor T3 may be provided as the light blocking electrode LBE3 of the third transistor T3.

As illustrated in FIG. 8, the second semiconductor layer SEL2 on the first interlayer insulating layer 124 may include the channel portion CH3, the first electrode portion E13, and the second electrode portion E23 of the third transistor T3.

The second semiconductor layer SEL2 may further include the second electrode portion E24 of the fourth transistor T4 electrically connected to the third node N3, along with the second electrode portion E23 of the third transistor T3.

That is, the second semiconductor layer SEL2 may further include a channel portion, a first electrode portion, and the second electrode portion E24 of the fourth transistor T4.

As illustrated in FIGS. 8, 9, and 10, according to one embodiment, the second semiconductor layer SEL2 may further include the first capacitor auxiliary electrode CPAE1 electrically connected to the first capacitor electrode CPE1.

The first capacitor auxiliary electrode CPAE1 may overlap a part of the first power line VDL, similarly to the first capacitor electrode CPE1.

In addition, according to one embodiment, the second semiconductor layer SEL2 may further include the second capacitor electrode CPE2 connected between the second electrode portion E23 of the third transistor T3 and the second electrode portion E24 of the fourth transistor T4.

The second capacitor electrode CPE2 may overlap a part of the scan write line GWL.

The second capacitor auxiliary electrode CPAE2 of the second gate conductive layer GCDL2 may be electrically connected to the second capacitor electrode CPE2.

The second capacitor auxiliary electrode CPAE2 may overlap a part of the scan write line GWL, similarly to the second capacitor electrode CPE2.

For example, the first semiconductor layer SEL1 may include a silicon semiconductor, and the second semiconductor layer SEL2 may include an oxide semiconductor.

The remaining portion of the first semiconductor layer SEL1, excluding the channel portion of each of the first transistor T1, the second transistor T2, the fifth transistor T5, the sixth transistor T6, and the seventh transistor T7, may be made electrically conductive by a dopant of a relatively high concentration.

Excluding the channel portion of each of the third transistor T3 and the fourth transistor T4 in the second semiconductor layer SEL2, the remaining part thereof may be electrically conductive by a dopant of a relatively high concentration or oxygen of a relatively low concentration.

The third gate conductive layer GCDL3 on the third gate insulating layer 125 may include the gate control line GCL.

The gate electrode G3 of the third transistor T3 may be provided as a portion of the gate control line GCL that overlaps the channel portion CH3 of the third transistor T3.

Meanwhile, the fourth transistor T4 may be turned on by the scan initialization signal GI of the scan initialization line GIL.

In this case, the third gate conductive layer GCDL3 may further include the scan initialization line GIL, and the second gate conductive layer GCDL2 may further include a scan initialization auxiliary line (not illustrated).

As illustrated in FIG. 7, the first source-drain conductive layer SDCDL1 may include the gate connection electrode GCE, the data connection electrode DCE, the first connection auxiliary electrode CNAE1, the second connection auxiliary electrode CNAE2, and the third connection auxiliary electrode CNAE3.

As illustrated in FIGS. 7 and 10, the gate connection electrode GCE may be electrically connected to the first capacitor electrode CPE1 including the gate electrode G1 of the first transistor T1, and the first capacitor auxiliary electrode CPAE1 of the second semiconductor layer SEL2, through the first capacitor connection hole CPCH1 overlapping one side of the gate connection electrode GCE.

As illustrated in FIG. 10, the first capacitor connection hole CPCH1 may extend through the second interlayer insulating layer 126, the third gate insulating layer 125, the first capacitor auxiliary electrode CPAE1, the first interlayer insulating layer 124, and the second gate insulating layer 123.

That is, as the first capacitor connection hole CPCH1 extends through the first capacitor auxiliary electrode CPAE1, the first capacitor auxiliary electrode CPAE1 may be in contact with the gate connection electrode GCE disposed in the first capacitor connection hole CPAH1.

Accordingly, the first capacitor auxiliary electrode CPAE1 of the second semiconductor layer SEL2 may be electrically connected to the first capacitor electrode CPE1 of the first gate conductive layer GCDL1 through the first capacitor connection hole CPCH1 and the gate connection electrode GCE.

In this way, the second semiconductor layer SEL2 of the circuit layer 120 according to one embodiment further includes the first capacitor auxiliary electrode CPAE1 electrically connected to the first capacitor electrode CPE1.

Accordingly, as illustrated in FIG. 10, the first pixel capacitor PC1 may be provided by an overlapping area between the first capacitor electrode CPE1 and the first power line VDL, and an overlapping area between the first capacitor auxiliary electrode CPAE1 and the first power line VDL.

In other words, the capacitance of the first pixel capacitor PC1 may be derived as the sum of a first capacitance C1 corresponding to the overlapping area between the first capacitor electrode CPE1 and the first power line VDL, and a second capacitance C2 due to the overlapping area between the first capacitor auxiliary electrode CPAE1 and the first power line VDL.

Accordingly, due to the disposition of the first capacitor auxiliary electrode CPAE1, the capacitance of the first pixel capacitor PC1 may be increased although the width of the first capacitor electrode CPE1 or the first power line VDL is not increased.

Since the first capacitor auxiliary electrode CPAE1 is disposed in the second semiconductor layer SEL2, a separate conductive layer and a separate insulating layer for disposition of the first capacitor auxiliary electrode CPAE1 are not required. Accordingly, the thickness of the circuit layer 120 does not have to increase even if the capacitance of the first pixel capacitor PC1 increases.

In addition, according to one embodiment, electrical connection between the first capacitor auxiliary electrode CPAE1 and the first capacitor electrode CPE1 may also be implemented by the first capacitor connection hole CPCH1 for electrical connection between the first capacitor electrode CPE1 and the gate connection electrode GCE. Accordingly, as a separate contact hole and a separate connection electrode for electrical connection between the first capacitor auxiliary electrode CPAE1 and the first capacitor electrode CPE1 are unnecessary, complexity of the circuit layer 120 may be prevented while the capacitance of the first pixel capacitor PC1 increases.

As illustrated in FIGS. 7 and 10, the gate connection electrode GCE may be electrically connected to the second capacitor electrode CPE2 of the second semiconductor layer SEL2 and the second capacitor auxiliary electrode CPAE2 of the second gate conductive layer GCDL2 through the second capacitor connection hole CPCH2 overlapping the other side of the gate connection electrode GCE.

As illustrated in FIG. 10, the second capacitor connection hole CPCH2 may extend through the second interlayer insulating layer 126, the third gate insulating layer 125, the second capacitor electrode CPE2, and the first interlayer insulating layer 124.

The second capacitor connection hole CPCH2 may extend to the second capacitor auxiliary electrode CPAE2.

The second capacitor connection hole CPCH2 may extend to the second capacitor auxiliary electrode CPAE2 but not into the second capacitor auxiliary electrode CPAE2.

That is, the second capacitor auxiliary electrode CPAE2 may prevent the second capacitor connection hole CPCH2 from extending to the second gate insulating layer 123 and the scan write line GWL while being formed through the second capacitor electrode CPE2.

As the second capacitor connection hole CPCH2 extends through the second capacitor electrode CPE2, the second capacitor electrode CPE2 may be in contact with the gate connection electrode GCE disposed in the second capacitor connection hole CPCH2.

Accordingly, the second capacitor electrode CPE2 of the second semiconductor layer SEL2 may be electrically connected to the second capacitor auxiliary electrode CPAE2 of the second gate conductive layer GCDL2 through the second capacitor connection hole CPCH2 and the gate connection electrode GCE.

In this way, the second gate conductive layer GCDL2 of the circuit layer 120 according to one embodiment further includes the second capacitor auxiliary electrode CPAE2 electrically connected to the second capacitor electrode CPE2.

Accordingly, as illustrated in FIG. 10, the second pixel capacitor PC2 may be provided by an overlapping area between the second capacitor electrode CPE2 and the scan write line GWL and an overlapping area between the second capacitor auxiliary electrode CPAE2 and the scan write line GWL.

In other words, the capacitance of the second pixel capacitor PC2 may be derived as the sum of a third capacitance C3 corresponding to the overlapping area between the second capacitor electrode CPE2 and the scan write line GWL, and a fourth capacitance C4 due to the overlapping area between the second capacitor auxiliary electrode CPAE2 and the scan write line GWL.

Accordingly, due to the disposition of the second capacitor auxiliary electrode CPAE2, the capacitance of the second pixel capacitor PC2 may be increased without also increasing the width of the second capacitor electrode CPE2 or the scan write line GWL.

Since the second capacitor auxiliary electrode CPAE2 is disposed on the second gate conductive layer GCDL2, a separate conductive layer and a separate insulating layer for disposition of the second capacitor auxiliary electrode CPAE2 are not required. Accordingly, the capacitance of the second pixel capacitor PC2 may increase without an increase in the thickness of the circuit layer 120.

In addition, according to one embodiment, electrical connection between the second capacitor auxiliary electrode CPAE2 and the second capacitor electrode CPE2 may also be implemented by the second capacitor connection hole CPCH2 for electrical connection between the second capacitor electrode CPE2 and the gate connection electrode GCE. Accordingly, as a separate contact hole and a separate connection electrode for electrical connection between the second capacitor auxiliary electrode CPAE2 and the second capacitor electrode CPE2 are unnecessary, complexity of the circuit layer 120 may be prevented while the capacitance of the second pixel capacitor PC2 increases.

As illustrated in FIGS. 7 and 9, the data connection electrode DCE may be electrically connected to the first electrode portion E12 of the second transistor T2 through the data auxiliary connection hole DCAH.

The first connection auxiliary electrode CNAE1 may be disposed for electrical connection between the first electrode portion E13 of the third transistor T3 and the first electrode portion E11 of the first transistor T1.

The first connection auxiliary electrode CNAE1 may be electrically connected to the first electrode portion E11 of the first transistor T1 through a first connection auxiliary hole CNAH1.

The first connection auxiliary electrode CNAE1 may be electrically connected to the first electrode portion E13 of the third transistor T3 through a second connection auxiliary hole CNAH2.

The first connection auxiliary hole CNAH1 may extend through the second interlayer insulating layer 126, the third gate insulating layer 125, the first interlayer insulating layer 124, the second gate insulating layer 123, and the first gate insulating layer 122.

The second connection auxiliary hole CNAH2 may extend through the second interlayer insulating layer 126 and the third gate insulating layer 125.

The second connection auxiliary electrode CNAE2 may be disposed for electrical connection between the first power line VDL of the second gate conductive layer GCDL2 and the first power auxiliary line VDAL of the second source-drain conductive layer SDCDL2.

The second connection auxiliary electrode CNAE2 may be electrically connected to the first power line VDL through a third connection auxiliary hole CNAH3.

The third connection auxiliary hole CNAH3 may extend through the second interlayer insulating layer 126, the third gate insulating layer 125, the first interlayer insulating layer 124, and the second gate insulating layer 123.

The third connection auxiliary electrode CNAE3 may be disposed for electrical connection between the second electrode portion of the seventh transistor T7 and the second electrode portion E26 of the sixth transistor T6.

The third connection auxiliary electrode CNAE3 may be electrically connected to the second electrode portion of the seventh transistor T7 through a fourth connection auxiliary hole CNAH4.

As illustrated in FIG. 7, the second source-drain conductive layer SDCDL2 may include the data line DL and the first power auxiliary line VDAL.

The data line DL and the first power auxiliary line VDAL each extend in the second direction DR2 and may be spaced apart from each other.

The data line DL may be electrically connected to the data connection electrode DCE through the data connection hole DCH extending through the first planarization layer 127.

The first power auxiliary line VDAL may be electrically connected to the second connection auxiliary electrode CNAE2 through a predetermined connection auxiliary hole (not illustrated) extending through the first planarization layer 127. Accordingly, the first power auxiliary line VDAL may be electrically connected to the first power line VDL. Accordingly, the first power ELVDD may be transmitted through mesh-shaped lines including the first power line VDL and the first power auxiliary line VDAL.

Next, a method for fabricating a display device according to one embodiment will be described.

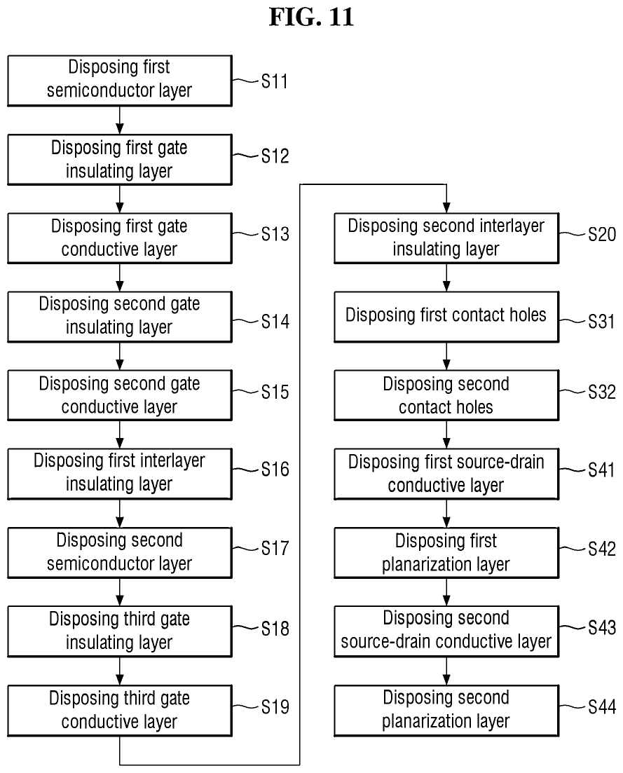

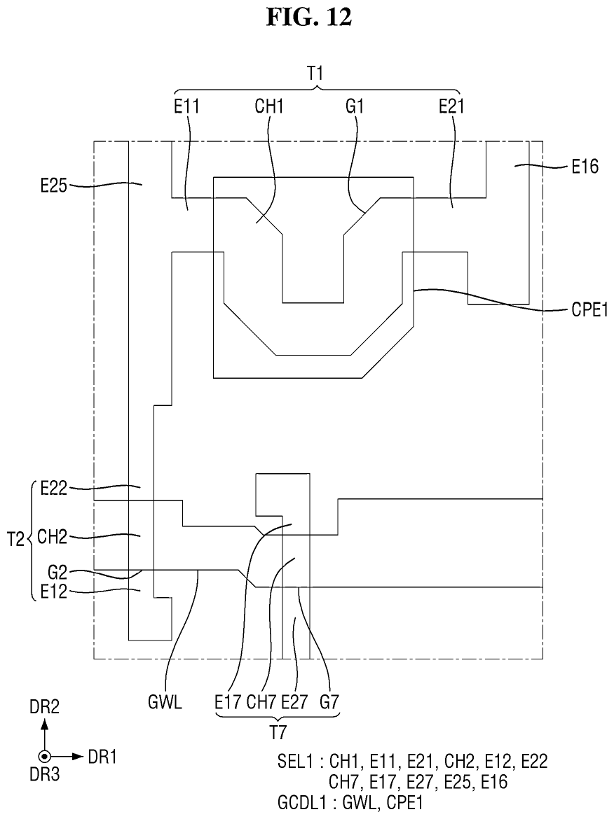

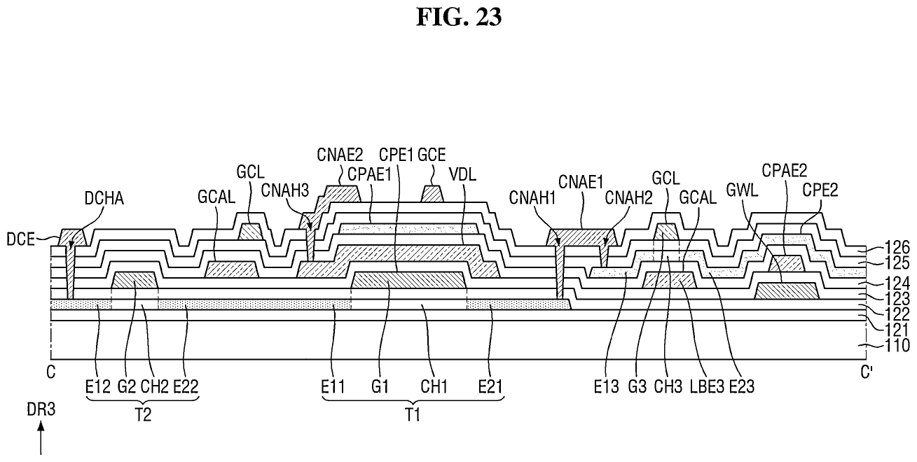

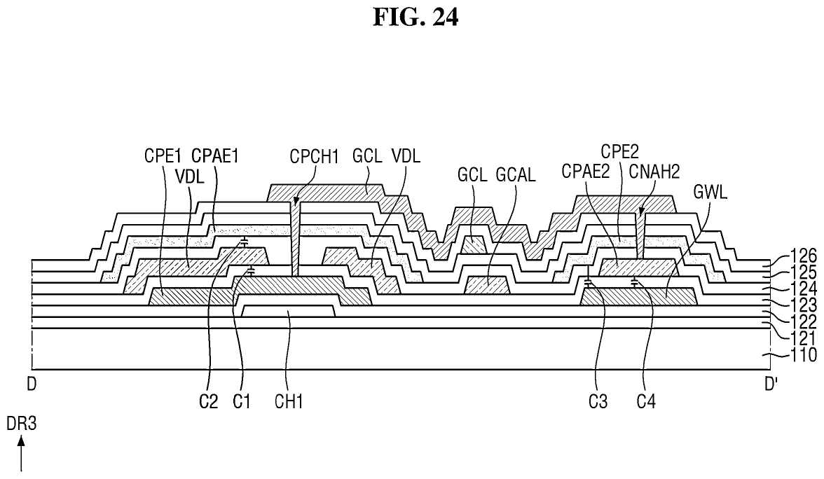

FIG. 11 is a flowchart illustrating a method for fabricating the display device according to one embodiment. FIGS. 12, 13, 14, 15, 16, 17, 18, 19, 20, 21, 22, 23, and 24 are process diagrams illustrating the process stages of FIG. 11.

Referring to FIGS. 3 and 4, a method for fabricating a display device according to one embodiment may include preparing the substrate 110 including the display area DA in which the emission areas EA are arranged, and disposing the circuit layer 120 including the light emitting pixel drivers EPD arranged adjacent to (e.g., parallel to each other) on the substrate 110.

The method for fabricating a display device according to one embodiment may further include disposing the element layer 130 on the circuit layer 120. The element layer 130 may include the light emitting elements LE that are respectively disposed in the emission areas EA and respectively electrically connected to the light emitting pixel drivers EPD.

Referring to FIG. 5, each of the light emitting pixel drivers EPD of the circuit layer 120 may include the first transistor T1 electrically connected between the first node N1 and the second node N2, and the first pixel capacitor PC1 electrically connected between the first power line VDL and the third node N3.

Referring to FIG. 11, disposing the circuit layer 120 may include disposing the first semiconductor layer SEL1 on the substrate 110 (process stage S11), disposing the first gate insulating layer 122 covering the first semiconductor layer SEL1 (process stage S12), disposing the first gate conductive layer GCDL1 on the first gate insulating layer 122 (process stage S13), disposing the second gate insulating layer 123 covering the first gate conductive layer GCDL1 (process stage S14), disposing the second gate conductive layer GCDL2 on the second gate insulating layer 123 (process stage S15), disposing the first interlayer insulating layer 124 covering the second gate conductive layer GCDL2 (process stage S16), disposing the second semiconductor layer SEL2 on the first interlayer insulating layer 124 (process stage S17), disposing the third gate insulating layer 125 covering the second semiconductor layer SEL2 (process stage S18), disposing the third gate conductive layer GCDL3 on the third gate insulating layer 125 (process stage S19), disposing the second interlayer insulating layer 126 covering the third gate conductive layer GCDL3 (process stage S20), disposing first contact holes that extend through two or more layers including at least the first interlayer insulating layer 124 among the second interlayer insulating layer 126, the third gate insulating layer 125, the second semiconductor layer SEL2, the first interlayer insulating layer 124, the second gate insulating layer 123, and the first gate insulating layer 122 (process stage S31), disposing at least one second contact hole penetrating at least one of the second interlayer insulating layer 126 or the third gate extending through layer 125 (process stage S32), disposing the first source-drain conductive layer SDCDL1 on the second interlayer insulating layer 126 (process stage S41), disposing the first planarization layer 127 covering the first source-drain conductive layer SDCDL1 (process stage S42), disposing the second source-drain conductive layer SDCDL2 on the first planarization layer 127 (process stage S43), and disposing the second planarization layer 128 covering the second source-drain conductive layer SDCDL2 (process stage S44).

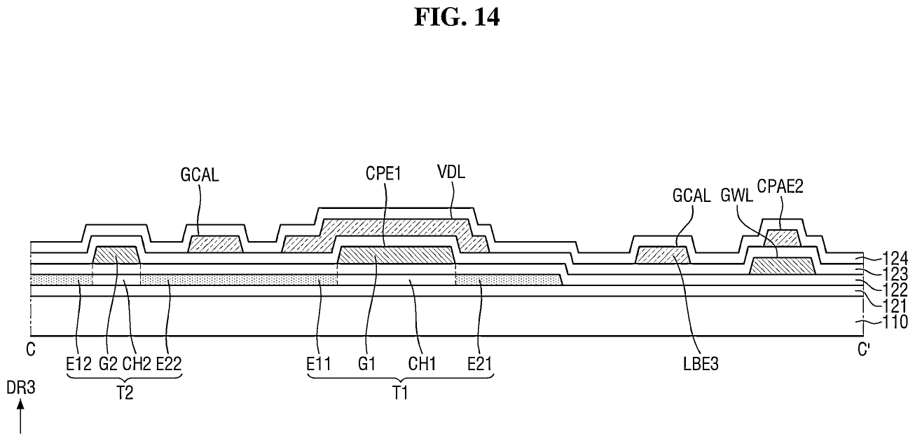

Referring to FIGS. 12 and 14, in process stage S11 of disposing the first semiconductor layer SEL1, the first semiconductor layer SEL1 may be disposed by partially removing the semiconductor material layer stacked on the substrate 110.

The first semiconductor layer SEL1 may include the channel portion CH1, the first electrode portion E11, and the second electrode portion E21 of the first transistor T1, the channel portion CH2, the first electrode portion E12, and the second electrode portion E22 of the second transistor T2, and the channel portion CH7, the first electrode portion E17, and the second electrode portion E27 of the seventh transistor T7.

The first semiconductor layer SEL1 may further include a channel portion, a first electrode portion, and a second electrode portion of each of the fifth transistor T5 and the sixth transistor T6.

In process stage S12 of disposing the first gate insulating layer 122 covering the first semiconductor layer SEL1, the first gate insulating layer 122 may be disposed by stacking an inorganic insulating material covering the first semiconductor layer SEL1 on the substrate 110.

In process stage S13 of disposing the first gate conductive layer GCDL1 on the first gate insulating layer 122, the first gate conductive layer GCDL1 may be disposed by partially removing a conductive material layer stacked on the first gate insulating layer 122.

The first gate conductive layer GCDL1 may include the first capacitor electrode CPE1 and the scan write line GWL.

The gate electrode G1 of the first transistor T1 may be provided as a portion of the first capacitor electrode CPE1 that overlaps the channel portion CH1 of the first transistor T1.

The gate electrode G2 of the second transistor T2 may be provided as a portion of the scan write line GWL that overlaps the channel portion CH2 of the second transistor T2.

In addition, the gate electrode G7 of the rear-stage seventh transistor T7 may be provided as another portion of the scan write line GWL that overlaps the channel portion CH7 of the rear-stage seventh transistor T7.

In process stage S14 of disposing the second gate insulating layer 123 covering the first gate conductive layer GCDL1, the second gate insulating layer 123 may be disposed by stacking the same material as the inorganic insulating material covering the first gate conductive layer GCDL1 on the first gate insulating layer 122.

After process stage S14 of disposing the second gate insulating layer 123, a dopant injection process is performed and, except for a portion of the first semiconductor layer SEL1 that overlaps the first gate conductive layer GCDL1, the remaining portion thereof may be made conductive by injecting a dopant of a relatively high concentration into the remaining portion of the first semiconductor layer SEL1. This dopant injection process may be performed before process S15.

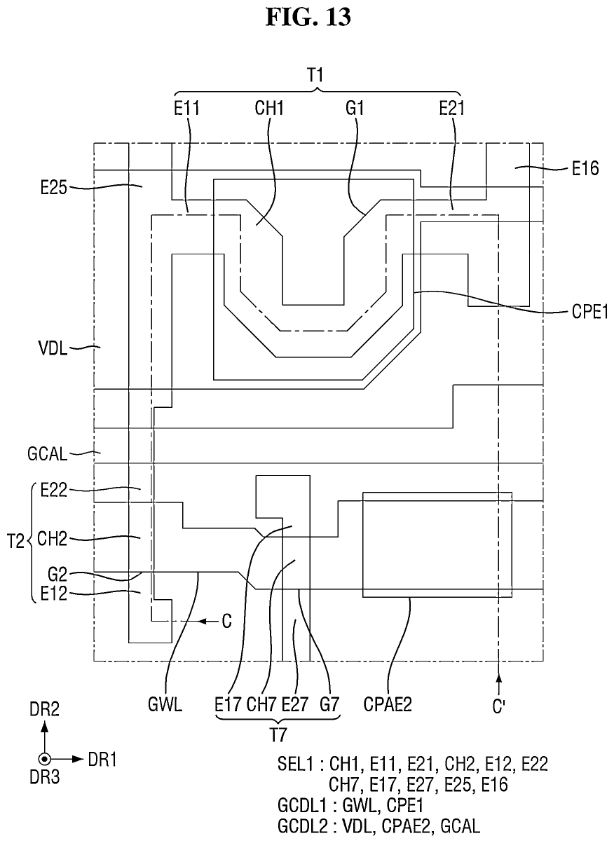

Referring to FIGS. 13 and 14, in process stage S15 of disposing the second gate conductive layer GCDL2 on the second gate insulating layer 123, the second gate conductive layer GCDL2 may be disposed by partially removing a conductive material layer stacked on the second gate insulating layer 123.

The second gate conductive layer GCDL2 may include the first power line VDL, the gate control auxiliary line GCAL, and the second capacitor auxiliary electrode CPAE2.

A part of the first power line VDL may overlap the first capacitor electrode CPE1.

A part of the scan write line GWL may overlap the second capacitor auxiliary electrode CPAE2.

In the process stage S16 of disposing the first interlayer insulating layer 124 covering the second gate conductive layer GCDL2, the first interlayer insulating layer 124 may be disposed by stacking an inorganic insulating material covering the second gate conductive layer GCDL2 on the second gate insulating layer 123.

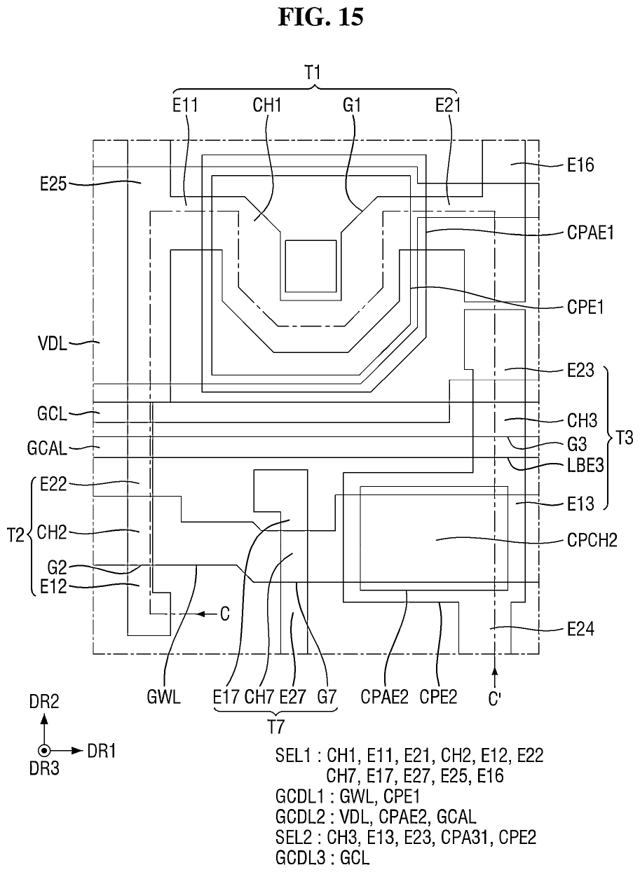

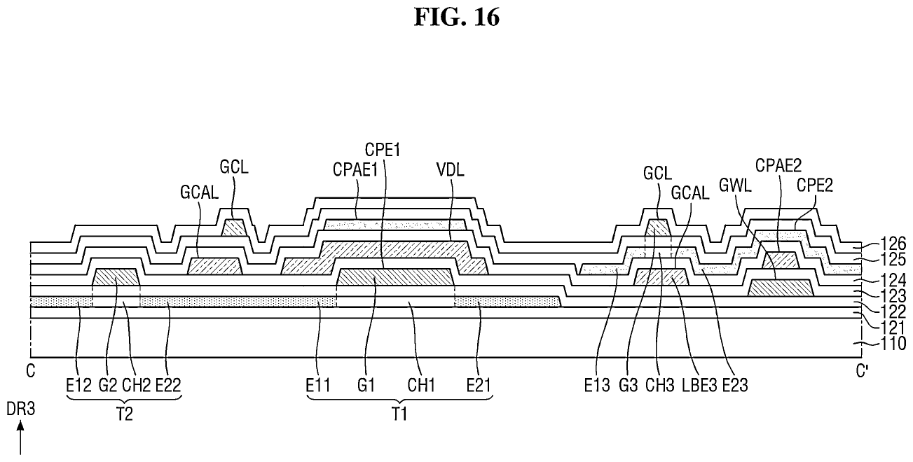

Referring to FIGS. 15 and 16, in process stage S17 of disposing the second semiconductor layer SEL2 on the first interlayer insulating layer 124, the second semiconductor layer SEL2 may be disposed by partially removing a semiconductor material layer stacked on the first interlayer insulating layer 124.

The second semiconductor layer SEL2 may include the channel portion CH3, the first electrode portion E13, and the second electrode portion E23 of the third transistor T3, the first capacitor auxiliary electrode CPAE1, and the second capacitor electrode CPE2.

The second semiconductor layer SEL2 may further include a channel portion, a first electrode portion, and the second electrode portion E24 of the fourth transistor T4.

The first capacitor auxiliary electrode CPAE1 may overlap the first capacitor electrode CPE1 and a part of the first power line VDL.

The second capacitor electrode CPE2 may be connected between the second electrode portion E23 of the third transistor T3 and the second electrode portion E24 of the fourth transistor T4.

The second capacitor electrode CPE2 may overlap the second capacitor auxiliary electrode CPAE2 and a part of the scan write line GWL.

In process stage S18 of disposing the third gate insulating layer 125 covering the second semiconductor layer SEL2, the third gate insulating layer 125 may be disposed by stacking the same material as the inorganic insulating material covering the second semiconductor layer SEL2 on the first interlayer insulating layer 124.

In process stage S19 of disposing the third gate conductive layer GCDL3 on the third gate insulating layer 125, the third gate conductive layer GCDL3 may be disposed by partially removing a conductive material layer stacked on the third gate insulating layer 125.

The third gate conductive layer GCDL3 may include the gate control line GCL.

The third gate conductive layer GCDL3 may further include the scan initialization line GIL.

The gate control line GCL may overlap at least a part of the gate control auxiliary line GCAL.

In process stage S20 of disposing the second interlayer insulating layer 126 covering the third gate conductive layer GCDL3, the second interlayer insulating layer 126 may be disposed by stacking an inorganic insulating material covering the third gate conductive layer GCDL3 on the third gate insulating layer 125.

After process stage S20 of disposing the second interlayer insulating layer 126, a dopant injection process is performed, and, except for a portion of the second semiconductor layer SEL2 that overlaps the third gate conductive layer GCDL3, the remaining portion of the second semiconductor layer SEL2 may be made conductive by injecting a dopant of a relatively high concentration into the remaining portion of the second semiconductor layer SEL2. This dopant injection process may be performed before process S31.

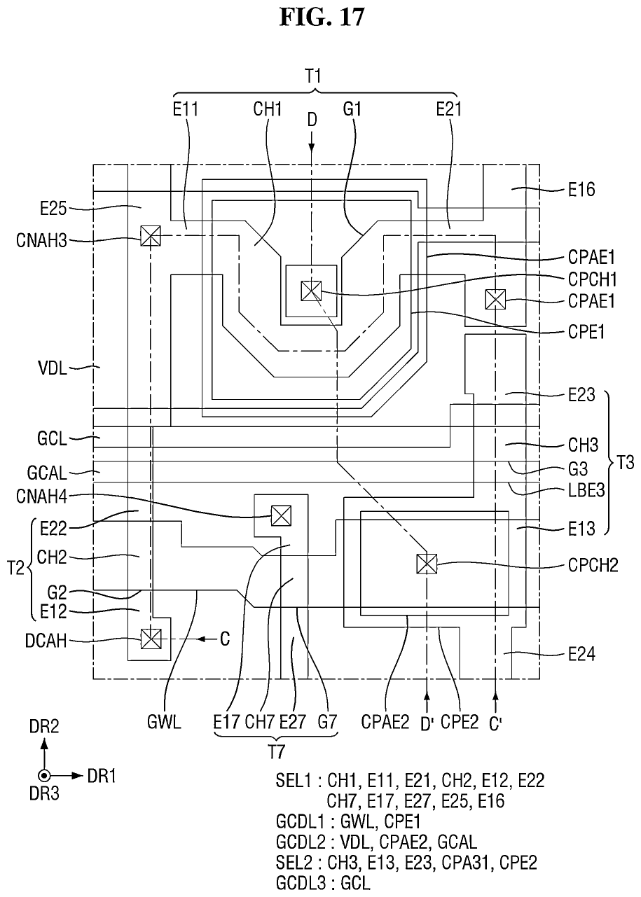

Referring to FIGS. 17, 18, and 19, in process stage S31 of disposing first contact holes through two or more layers including at least the first interlayer insulating layer 124 among the second interlayer insulating layer 126, the third gate insulating layer 125, the second semiconductor layer SEL2, the first interlayer insulating layer 124, the second gate insulating layer 123, and the first gate insulating layer 122, the first contact holes may be formed by performing an etching process on oxide or nitride.

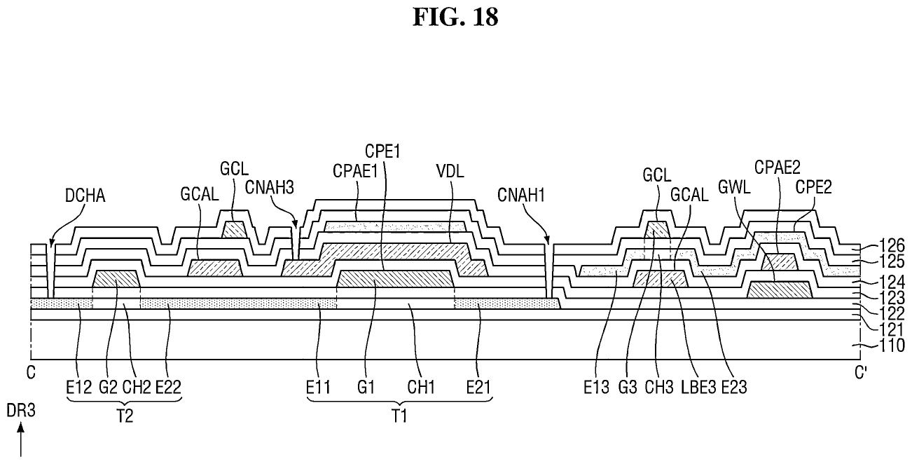

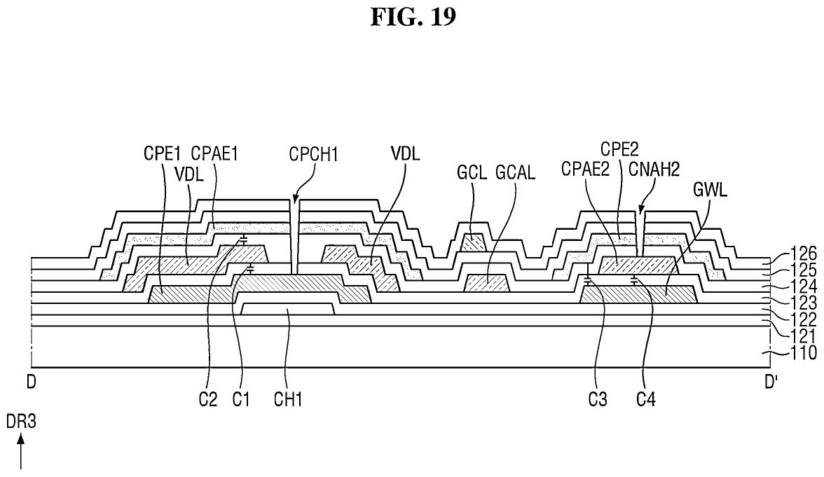

As illustrated in FIGS. 18 and 19, the first contact holes may extend through the second interlayer insulating layer 126 and the third gate insulating layer 125, extend further toward the substrate 110, and further extend through at least one of the first interlayer insulating layer 124, the second gate insulating layer 123, or the first gate insulating layer 122.

Accordingly, the etching process in process stage S31 of disposing the first contact holes may be performed by dry etching using an etching material with a relatively high oxide or nitride etching rate.

As an example, the etching material used in process stage S31 of disposing the first contact holes may include carbon tetrafluoride (CF₄) and oxygen (O₂).

This way, the processing time for the etching process in process stage S31 of disposing the first contact holes may be shortened.

For example, as illustrated in FIG. 17, the first contact holes may include the first capacitor connection hole CPCH1, the second capacitor connection hole CPCH2, the data auxiliary connection hole DCAH, the first connection auxiliary hole CNAH1, the third connection auxiliary hole CNAH3, and the fourth connection auxiliary hole CNAH4.

As illustrated in FIG. 19, among the first contact holes, the first capacitor connection hole CPCH1 and the second capacitor connection hole CPCH2 further extend through the second semiconductor layer SEL2.

As a result, the first capacitor auxiliary electrode CPAE1 of the second semiconductor layer SEL2 may be partially exposed through the side surface of the first capacitor connection hole CPCH1 at the end of process S31.

The first capacitor connection hole CPCH1 may extend to the first capacitor electrode CPE1 of the first gate conductive layer GCDL1 and may expose the first capacitor electrode CPE1.

In addition, the second capacitor electrode CPE2 of the second semiconductor layer SEL2 may be exposed through the side surface of the second capacitor connection hole CPCH2.

The second capacitor connection hole CPCH2 may extend to the second capacitor auxiliary electrode CPAE2 of the second gate conductive layer GCDL2, and may expose the second capacitor auxiliary electrode CPAE2.

That is, the second capacitor auxiliary electrode CPAE2 may be a stopper that prevents the second capacitor connection hole CPCH2 from extending past CPAE2. Accordingly, the second capacitor connection hole CPCH2 may be prevented from extending into the scan write line GWL.

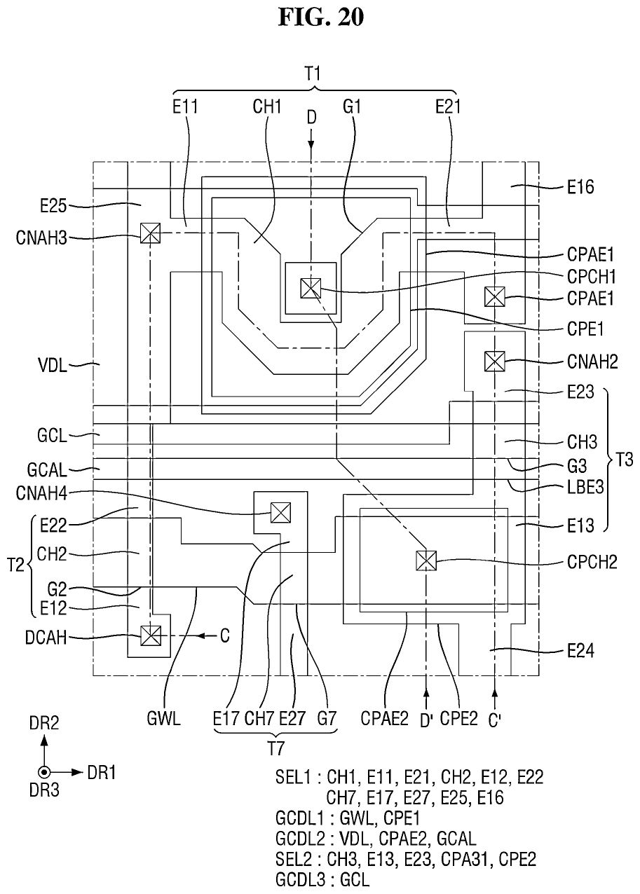

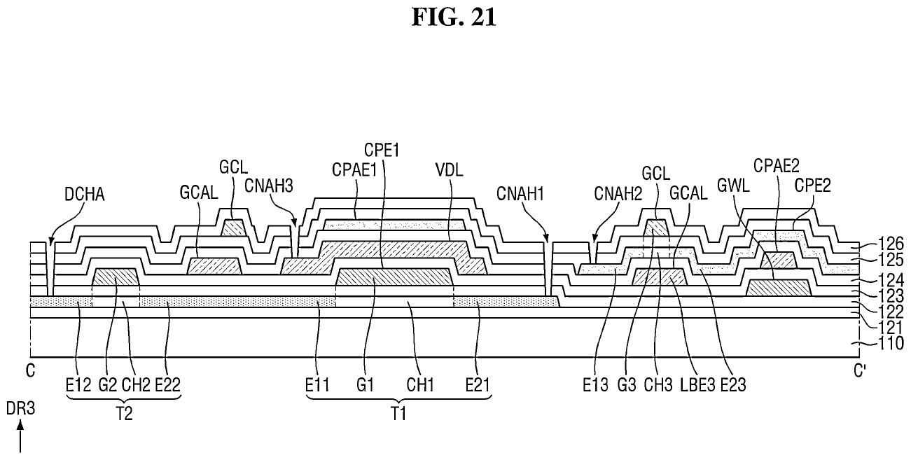

Referring to FIGS. 20 and 21, in process stage S32 of disposing at least one second contact hole that extends through at least one of the second interlayer insulating layer 126 or the third gate insulating layer 125, at least one second contact hole may be disposed by performing an etching process on the second interlayer insulating layer 126 and the third gate insulating layer 125.

Each of the at least one second contact hole may extend through the second interlayer insulating layer 126 to come in contact with the third gate conductive layer GCDL3, or may extend through the second interlayer insulating layer 126 and the third gate insulating layer 125 to come in contact with the second semiconductor layer SEL2.

For example, as illustrated in FIG. 20, at least one second contact hole may include the second connection auxiliary hole CNAH2.

The etching process in process stage S32 of disposing at least one second contact hole may be performed by dry etching using an etching material with a relatively low oxide etching rate.

For example, the etching material used in process stage S32 of disposing at least one second contact hole may include carbon tetrafluoride (CF₄) and argon (Ar).

This way, extension of the second contact hole into the second semiconductor layer SEL2 may be prevented.

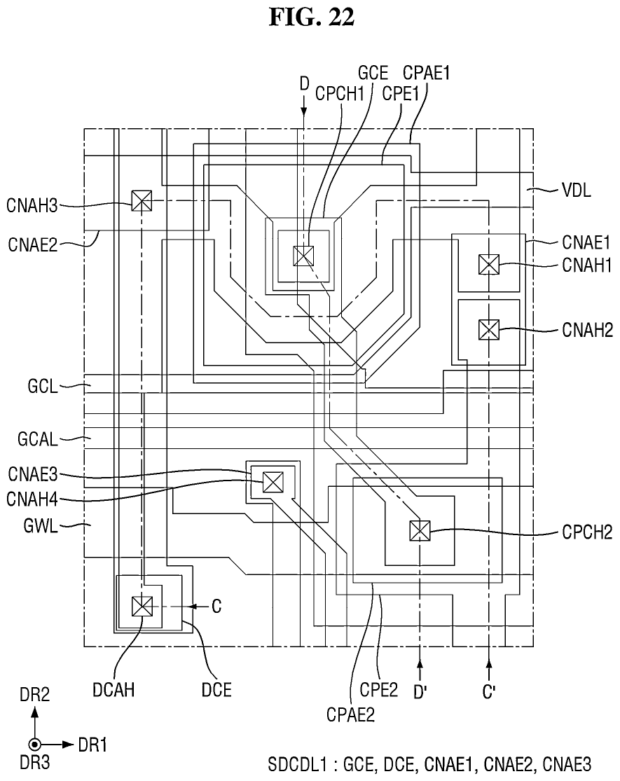

Referring to FIGS. 22, 23, and 24, process stage S41 of disposing the first source-drain conductive layer SDCDL1 on the second interlayer insulating layer 126, the first source-drain conductive layer SDCDL1 may be disposed by partially removing a conductive material layer that is on the second interlayer insulating layer 126.

The first source-drain conductive layer SDCDL1 may include the gate connection electrode GCE, the data connection electrode DCE, the first connection auxiliary electrode CNAE1, the second connection auxiliary electrode CNAE2, and the third connection auxiliary electrode CNAE3.

In addition, the first source-drain conductive layer SDCDL1 may further include the first anode connection electrode ANCE1 (see FIG. 6).

The gate connection electrode GCE may be electrically connected to the first capacitor electrode CPE1 and the first capacitor auxiliary electrode CPAE1 through the first capacitor connection hole CPCH1.

The gate connection electrode GCE may be electrically connected to the second capacitor electrode CPE2 and the second capacitor auxiliary electrode CPAE2 through the second capacitor connection hole CPCH2.

The first node N1, which is electrical connection between the second electrode portion E23 of the third transistor T3 and the second electrode portion E24 of the fourth transistor T4, and the gate electrode G1 of the first transistor T1, may be provided by the gate connection electrode GCE.

The data connection electrode DCE may be electrically connected to the first electrode portion E12 of the second transistor T2 through the data auxiliary connection hole DCAH.

The first connection auxiliary electrode CNAE1 may be electrically connected to the first electrode portion E11 of the first transistor T1 through the first connection auxiliary hole CNAH1, and may be electrically connected to the first electrode portion E13 of the third transistor T3 through the second connection auxiliary hole CNAH2.

The third node N3, which is electrical connection between the first electrode portion E11 of the first transistor T1 and the first electrode portion E13 of the third transistor T3, may be provided by the first connection auxiliary electrode CNAE1.

The second connection auxiliary electrode CNAE2 may be electrically connected to the first power line VDL through the third connection auxiliary hole CNAH3.

The third connection auxiliary electrode CNAE3 may be electrically connected to the second electrode portion of the seventh transistor T7 through a fourth connection auxiliary hole CNAH4.

In process stage S42 of disposing the first planarization layer 127 covering the first source-drain conductive layer SDCDL1, the first planarization layer 127 may be disposed by applying an organic insulating material covering the first source-drain conductive layer SDCDL1 on the second interlayer insulating layer 126.

Referring to FIGS. 7, 9, and 10, in process stage S43 of disposing the second source-drain conductive layer SDCDL2 on the first planarization layer 127, the second source-drain conductive layer SDCDL2 may be disposed by partially removing a conductive material layer stacked on the first planarization layer 127.

The second source-drain conductive layer SDCDL2 may include the data line DL and the first power auxiliary line VDAL.

In addition, the second source-drain conductive layer SDCDL2 may further include the second anode connection electrode ANCE2 (see FIG. 6).

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising a display area having emission areas;
a circuit layer disposed on the substrate; and
an element layer disposed on the circuit layer,
wherein the circuit layer comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer; and
a second interlayer insulating layer covering the third gate conductive layer,
wherein the second gate conductive layer comprises a first power line that transmits a first power,
the first gate conductive layer comprises a first capacitor electrode that overlaps a part of the first power line, and
the second semiconductor layer comprises a first capacitor auxiliary electrode electrically connected to the first capacitor electrode.

2. The display device of claim 1, wherein the element layer comprises light emitting elements respectively disposed in the emission areas,
the circuit layer comprises light emitting pixel drivers that are respectively electrically connected to the light emitting elements and arranged adjacent to each other, and
each of the light emitting pixel drivers comprises:
a first transistor electrically connected between a first node and a second node;
a first pixel capacitor electrically connected between the first power line and a third node;
a second transistor electrically connected between the first node and a data line that transmits a data signal;
a third transistor electrically connected between the second node and the third node; and
a fourth transistor electrically connected between the third node and a gate initialization voltage line that transmits a gate initialization voltage,
wherein the first node is electrically connected to a first electrode of the first transistor,
the second node is electrically connected to a second electrode of the first transistor, and
the third node is electrically connected to a gate electrode of the first transistor.

3. The display device of claim 2, wherein each of the first transistor and the second transistor comprises a channel portion, a first electrode portion, and a second electrode portion disposed in the first semiconductor layer, and a gate electrode disposed in the first gate conductive layer and overlapping the channel portion,
each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode,
the first electrode portion is connected to one side of the channel portion,
the second electrode portion is connected to the other side of the channel portion, and
a remaining portion of the second semiconductor layer, excluding the channel portion of the third transistor and the channel portion of the fourth transistor, is conductive.

4. The display device of claim 3, wherein the gate electrode of the first transistor comprises a portion of the first capacitor electrode that overlaps the channel portion of the first transistor, and
the first pixel capacitor is provided by an overlapping area between the first capacitor electrode and the first power line and an overlapping area between the first capacitor auxiliary electrode and the first power line.

5. The display device of claim 4, wherein the circuit layer further comprises:
a first source-drain conductive layer disposed on the second interlayer insulating layer;
a first planarization layer covering the first source-drain conductive layer;
a second source-drain conductive layer disposed on the first planarization layer; and
a second planarization layer covering the second source-drain conductive layer,
wherein the first source-drain conductive layer further comprises a gate connection electrode that electrically connects the second electrode portion of the third transistor and the second electrode portion of the fourth transistor to the gate electrode of the first transistor,
the gate connection electrode is electrically connected to the first capacitor electrode and the first capacitor auxiliary electrode through a first capacitor connection hole extending to the gate connection electrode, and
the first capacitor connection hole extends to the second interlayer insulating layer, the third gate insulating layer, the first capacitor auxiliary electrode, the first interlayer insulating layer, and the second gate insulating layer.

6. The display device of claim 5, wherein the first capacitor auxiliary electrode is electrically connected to the first capacitor electrode through the first capacitor connection hole and the gate connection electrode.

7. The display device of claim 5, wherein the second transistor is turned on by a scan write signal of a scan write line,
each of the light emitting pixel drivers further comprises:
a second pixel capacitor electrically connected between the scan write line and the third node;
a fifth transistor electrically connected between the first power line and the first node;
a sixth transistor electrically connected between the second node and a fourth node; and
a seventh transistor electrically connected between the fourth node and an anode initialization voltage line that transmits an anode initialization voltage,
wherein the fourth node is electrically connected to one of the light emitting elements.

8. The display device of claim 7, wherein the first gate conductive layer further comprises the scan write line,
the second semiconductor layer further comprises a second capacitor electrode connected to the second electrode portion of the third transistor and the second electrode portion of the fourth transistor and overlapping a part of the scan write line,
the second gate conductive layer further comprises a second capacitor auxiliary electrode electrically connected to the second capacitor electrode, and
the second pixel capacitor is provided by an overlapping area between the second capacitor electrode and the scan write line and an overlapping area between the second capacitor auxiliary electrode and the scan write line.

9. The display device of claim 8, wherein the gate electrode of the second transistor is provided as another portion of the scan write line that overlaps the channel portion of the second transistor.

10. The display device of claim 8, wherein the gate connection electrode is electrically connected to the second capacitor electrode and the second capacitor auxiliary electrode through a second capacitor connection hole that extends to the gate connection electrode, and
the second capacitor connection hole extends through the second interlayer insulating layer, the third gate insulating layer, the second capacitor electrode, and the first interlayer insulating layer, and is in contact with the second capacitor auxiliary electrode.

11. The display device of claim 10, wherein the second capacitor auxiliary electrode is electrically connected to the second capacitor electrode through the second capacitor connection hole and the gate connection electrode.

12. A display device comprising:
a substrate comprising a display area having emission areas;
a circuit layer disposed on the substrate; and
an element layer disposed on the circuit layer,
wherein the circuit layer comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer;
a second interlayer insulating layer covering the third gate conductive layer;
a first source-drain conductive layer disposed on the second interlayer insulating layer;
a first planarization layer covering the first source-drain conductive layer;
a second source-drain conductive layer disposed on the first planarization layer; and
a second planarization layer covering the second source-drain conductive layer,
the element layer comprises light emitting elements respectively disposed in the emission areas,
the circuit layer comprises light emitting pixel drivers that are respectively electrically connected to the light emitting elements and arranged adjacent to each other, and
each of the light emitting pixel drivers comprises:
a first transistor electrically connected between a first node and a second node; and
a first pixel capacitor electrically connected between a third node and a first power line that transmits a first power,
wherein the first node is electrically connected to a first electrode of the first transistor,
the second node is electrically connected to a second electrode of the first transistor, and
the third node is electrically connected to a gate electrode of the first transistor,
the first pixel capacitor is provided by an overlapping area between the first capacitor electrode and the first power line and an overlapping area between the first capacitor auxiliary electrode and the first power line,
the first capacitor electrode is disposed in the first gate conductive layer and comprises the gate electrode of the first transistor,
the first power line is disposed in the second gate conductive layer,
the first capacitor auxiliary electrode is disposed in the second semiconductor layer, and electrically connected to the first capacitor electrode through a gate connection electrode and a first capacitor connection hole that extends to the gate connection electrode,
the gate connection electrode is disposed in the first source-drain conductive layer, and
the first capacitor connection hole extends through the second interlayer insulating layer, the third gate insulating layer, the first capacitor auxiliary electrode, the first interlayer insulating layer, and the second gate insulating layer.

13. The display device of claim 12, wherein each of the light emitting pixel drivers further comprises:
a second transistor electrically connected between the third node and a data line that transmits a data signal, and turned on by a scan write signal of a scan write line;
a third transistor electrically connected between the second node and the third node;
a fourth transistor electrically connected between the third node and a gate initialization voltage line that transmits a gate initialization voltage;
a second pixel capacitor electrically connected between the scan write line and the third node;
a fifth transistor electrically connected between the first power line and the first node;
a sixth transistor electrically connected between the second node and the fourth node; and
a seventh transistor electrically connected between the fourth node and an anode initialization voltage line that transmits an anode initialization voltage,
wherein each of the first transistor, the second transistor, the fifth transistor, the sixth transistor, and the seventh transistor comprises a channel portion, a first electrode portion, and a second electrode portion disposed in the first semiconductor layer, and a gate electrode disposed in the first gate conductive layer and overlapping the channel portion,
each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode,
the first electrode portion is connected to one side of the channel portion,
the second electrode portion is connected to the other side of the channel portion, and
a remaining portion of the second semiconductor layer, excluding the channel portion of the third transistor and the channel portion of the fourth transistor, is conductive.

14. The display device of claim 13, wherein the second pixel capacitor is provided by an overlapping area between the second capacitor electrode and the scan write line and an overlapping area between the second capacitor auxiliary electrode and the scan write line,
the scan write line is disposed in the first gate conductive layer,
the second capacitor electrode is disposed in the second semiconductor layer and connected to the second electrode portion of the third transistor and the second electrode portion of the fourth transistor,
the second capacitor auxiliary electrode is disposed in the second gate conductive layer, and electrically connected to the second capacitor electrode through the gate connection electrode and a second capacitor connection hole that extends to the gate connection electrode, and
the second capacitor connection hole extends through the second interlayer insulating layer, the third gate insulating layer, the second capacitor electrode, and the first interlayer insulating layer, and is in contact with the second capacitor auxiliary electrode.

15. A method for fabricating a display device, comprising:
providing a substrate comprising a display area having emission areas arranged; and
disposing, on the substrate, a circuit layer comprising light emitting pixel drivers arranged adjacent to each other,
wherein each of the light emitting pixel drivers comprises:
a first transistor electrically connected between a first node and a second node; and
a first pixel capacitor electrically connected between a third node and a first power line that transmits a first power,
wherein the first node is electrically connected to a first electrode of the first transistor,
the second node is electrically connected to a second electrode of the first transistor, and
the third node is electrically connected to a gate electrode of the first transistor, and
the disposing of the circuit layer comprises:
disposing a first semiconductor layer on the substrate;
disposing a first gate insulating layer covering the first semiconductor layer;
disposing a first gate conductive layer on the first gate insulating layer;
disposing a second gate insulating layer covering the first gate conductive layer;
disposing a second gate conductive layer on the second gate insulating layer;
disposing a first interlayer insulating layer covering the second gate conductive layer;
disposing a second semiconductor layer on the first interlayer insulating layer;
disposing a third gate insulating layer covering the second semiconductor layer;
disposing a third gate conductive layer on the third gate insulating layer;
disposing a second interlayer insulating layer covering the third gate conductive layer;
disposing first contact holes extending through two or more layers comprising the first interlayer insulating layer among the second interlayer insulating layer, the third gate insulating layer, the second semiconductor layer, the first interlayer insulating layer, the second gate insulating layer, and the first gate insulating layer;
disposing at least one second contact hole extending through at least one of the second interlayer insulating layer or the third gate insulating layer;
disposing a first source-drain conductive layer on the second interlayer insulating layer;
disposing a first planarization layer covering the first source-drain conductive layer;
disposing a second source-drain conductive layer on the first planarization layer; and
disposing a second planarization layer covering the second source-drain conductive layer,
wherein the second gate conductive layer comprises the first power line,
the first gate conductive layer comprises a first capacitor electrode that overlaps a part of the first power line,
the second semiconductor layer comprises a first capacitor auxiliary electrode electrically connected to the first capacitor electrode,
the first source-drain conductive layer comprises a gate connection electrode electrically connected to the first capacitor electrode and the first capacitor auxiliary electrode,
the gate electrode of the first transistor is provided as a part of the first capacitor electrode,
the first capacitor auxiliary electrode is electrically connected to the first capacitor electrode through the gate connection electrode and a first capacitor connection hole extending to the gate connection electrode,
the first contact holes comprise the first capacitor connection hole extending through the second interlayer insulating layer, the third gate insulating layer, the first capacitor auxiliary electrode, the first interlayer insulating layer, and the second gate insulating layer, and
the first pixel capacitor is provided by an overlapping area between the first capacitor electrode and the first power line and an overlapping area between the first capacitor auxiliary electrode and the first power line.

16. The method of claim 15, wherein each of the light emitting pixel drivers further comprises:
a second transistor electrically connected between the third node and a data line that transmits a data signal, and turned on by a scan write signal of a scan write line;
a third transistor electrically connected between the second node and the third node;
a fourth transistor electrically connected between the third node and a gate initialization voltage line that transmits a gate initialization voltage;
a second pixel capacitor electrically connected between the scan write line and the third node;
a fifth transistor electrically connected between the first power line and the first node;
a sixth transistor electrically connected between the second node and the fourth node; and
a seventh transistor electrically connected between the fourth node and an anode initialization voltage line that transmits an anode initialization voltage,
wherein each of the first transistor, the second transistor, the fifth transistor, the sixth transistor, and the seventh transistor comprises a channel portion, a first electrode portion, and a second electrode portion disposed in the first semiconductor layer, and a gate electrode disposed in the first gate conductive layer and overlapping the channel portion,
each of the third transistor and the fourth transistor comprises a channel portion, a first electrode portion, and a second electrode portion disposed in the second semiconductor layer, a gate electrode disposed in the third gate conductive layer and overlapping the channel portion, and a light blocking electrode disposed in the second gate conductive layer and overlapping the channel portion and the gate electrode,
the first electrode portion is connected to one side of the channel portion,
the second electrode portion is connected to the other side of the channel portion, and
a remaining portion of the second semiconductor layer, excluding the channel portion of the third transistor and the channel portion of the fourth transistor, is conductive.

17. The method of claim 16, wherein the first gate conductive layer further comprises the scan write line,
the second semiconductor layer further comprises a second capacitor electrode connected to the second electrode portion of the third transistor and the second electrode portion of the fourth transistor and overlapping a part of the scan write line,
the second gate conductive layer further comprises a second capacitor auxiliary electrode electrically connected to the second capacitor electrode,
the second capacitor auxiliary electrode is electrically connected to the second capacitor electrode through the gate connection electrode and a second capacitor connection hole that extends to the gate connection electrode,
the first contact holes further comprise the second capacitor connection hole extending through the second interlayer insulating layer, the third gate insulating layer, the second capacitor electrode, and the first interlayer insulating layer, and
the second pixel capacitor is provided by an overlapping area between the second capacitor electrode and the scan write line and an overlapping area between the second capacitor auxiliary electrode and the scan write line.

18. The method of claim 17, wherein in the disposing of the first contact holes, the second capacitor connection hole is in contact with the second capacitor auxiliary electrode.

19. The method of claim 16, wherein:
The disposing of the first contact holes comprises using an etching material that contains carbon tetrafluoride (CF₄) and oxygen (O₂), and
the disposing of the second contact hole comprises using an etching material that contains carbon tetrafluoride (CF₄) and argon (Ar).
